(19) United States
(12) Patent Application Publication
(10) Pub. No.: US 2025/0133788 A1
(43) Pub. Date: Apr. 24, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Ta-Chun LIN, Hsinchu (TW)

(21) Appl. No.: 18/491,889

(22) Filed: Oct. 23, 2023

(51) Int. Cl. H01L 29/06; H01L 21/8234; H01L 27/088; H01L 29/417; H01L 29/423; H01L 29/66; H01L 29/775; H01L 29/786

(52) U.S. Cl. CPC H10D 62/121; H10D 30/014; H10D 30/43; H10D 30/6729; H10D 30/6735; H10D 30/6757; H10D 64/017; H10D 64/021; H10D 84/0147; H10D 84/0151; H10D 84/038; H10D 84/83

(57) ABSTRACT

Semiconductor structures and methods for manufacturing the same are provided. The semiconductor structure includes first nanostructures formed over a substrate along a first direction, and second nanostructures formed over the substrate along the first direction. The semiconductor structure includes a first gate structure formed over the first nanostructures along a second direction, and a first S/D structure formed adjacent to the first gate structure. The semiconductor structure includes a second gate structure formed over the second nanostructures along the second direction, and a second S/D structure formed adjacent to the second gate structure. The semiconductor structure includes a dielectric wall structure formed along the first direction. The dielectric wall structure includes a first portion between the first S/D structure and the second S/D structure and a second portion between the first gate structure and the second gate structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIG. 2 shows a top-view representation of the semiconductor structure, in accordance with some embodiments.

FIGS. 3A-1 to 3L-1 illustrate cross-sectional representations of various stages of manufacturing the semiconductor structure shown along line A-A′ in FIGS. 1E and 1n FIG. 2, in accordance with some embodiments.

FIGS. 3A-2 to 3L-2 illustrate cross-sectional representations of various stages of manufacturing the semiconductor structure shown along line B-B′ in FIGS. 1E and 1n FIG. 2, in accordance with some embodiments.

FIGS. 3A-3 to 3L-3 illustrate cross-sectional representations of various stages of manufacturing the semiconductor structure shown along line C-C′ in FIGS. 1E and 1n FIG. 2, in accordance with some embodiments.

FIG. 3L′-1 illustrates a cross-sectional representation of a semiconductor structure, in accordance with some embodiments.

FIG. 4 shows a top-view representation of the semiconductor structure after forming the dielectric wall structure, in accordance with some embodiments.

FIG. 5 shows a top-view representation of a semiconductor structure, in accordance with some embodiments.

FIG. 6 illustrates a cross-sectional representation of the semiconductor structure shown along line A-A′ in FIG. 5, in accordance with some embodiments.

FIG. 7 illustrates a cross-sectional representation of the semiconductor structure shown along line B-B′ in FIG. 5, in accordance with some embodiments.

FIGS. 8A-1 to 8E-1 illustrate cross-sectional representations of various stages of manufacturing a semiconductor structure shown along line A-A′ in FIGS. 1E and 1n FIG. 2, in accordance with some embodiments.

FIGS. 8A-2 to 8E-2 illustrate cross-sectional representations of various stages of manufacturing the semiconductor structure shown along line B-B′ in FIGS. 1E and 1n FIG. 2, in accordance with some embodiments.

FIGS. 8A-3 to 8E-3 illustrate cross-sectional representations of various stages of manufacturing the semiconductor structure shown along line C-C′ in FIGS. 1E and 1n FIG. 2, in accordance with some embodiments.

FIG. 9 shows a top-view representation of the semiconductor structure after forming the dielectric wall structure, in accordance with some embodiments.

FIG. 10 shows a top-view representation of a semiconductor structure, in accordance with some embodiments.

FIG. 11 illustrates a cross-sectional representation of the semiconductor structure shown along line A-A′ in FIG. 7, in accordance with some embodiments.

FIG. 12 illustrates a cross-sectional representation of the semiconductor structure shown along line B-B′ in FIG. 7, in accordance with some embodiments.

FIG. 13A shows a top-view representation of a semiconductor structure after forming a first dielectric wall structure, in accordance with some embodiments.

FIG. 13B shows a top-view representation of a semiconductor structure after forming a second dielectric wall structure, in accordance with some embodiments.

FIGS. 14A-1 to 14E-1 illustrate cross-sectional representations of various stages of manufacturing the semiconductor structure shown along line D-D′ in FIGS. 13A and 13B, in accordance with some embodiments.

FIG. 14E′-1 illustrates a cross-sectional representation of a semiconductor structure 100g shown along line D-D′ in FIG. 13B,

FIGS. 14A-2 to 14E-2 illustrate cross-sectional representations of various stages of manufacturing the semiconductor structure shown along line E-E′ in FIGS. 13A and 13B, in accordance with some embodiments.

FIGS. 14A-3 to 14E-3 illustrate cross-sectional representations of various stages of manufacturing the semiconductor structure shown along line F-F′ in FIGS. 13A and 13B, in accordance with some embodiments.

FIGS. 14A-4 to 14E-4 illustrate cross-sectional representations of various stages of manufacturing the semiconductor structure shown along line G-G′ in FIGS. 13A and 13B, in accordance with some embodiments.

FIG. 15 shows a top-view representation of a semiconductor structure, in accordance with some embodiments.

FIG. 16 illustrates a cross-sectional representation of the semiconductor structure 100h shown along line E-E′ in FIG. 15, in accordance with some embodiments.

FIG. 17 illustrates a cross-sectional representation of the semiconductor structure shown along line F-F′ in FIG. 15, in accordance with some embodiments.

FIGS. 18A to 18G illustrate cross-sectional representations of various stages of manufacturing a semiconductor structure shown along line F-F′ in FIGS. 13A and 13B, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a first fin structure and a second fin structure formed over a substrate. The first fin structure includes first nanostructures, and the second fin structure includes second nanostructures along a first direction (e.g. x-axis). A first gate structure formed over the first nanostructures along the second direction (e.g. y-direction) and a second gate structure formed along the second direction (e.g. y-direction). In some embodiments, the dielectric wall structure has a first portion and a second portion, the first portion is between two adjacent S/D structures, and the second portion is between the first gate structure and the second gate structure. In some embodiments, the first dielectric wall structure and the second dielectric wall structure are formed by two different steps. The first dielectric wall structure and the second dielectric wall structure are parallel to each other along the first direction (e.g. x-axis). The first dielectric wall structure is between two adjacent S/D structures, and the second dielectric wall structure is between the first gate structure and the second gate structure. Since the two adjacent S/D structures are isolated or separated from the dielectric wall structure, the first dielectric wall structure or the second dielectric wall structure, the unwanted connection between the two adjacent S/D structures can be prevented. Therefore, the leakage of the semiconductor structures is reduced, and the performances of the semiconductor structures are improved. The source/drain (S/D) structure or region(s) may refer to a source or a drain, individually or collectively dependent upon the context.

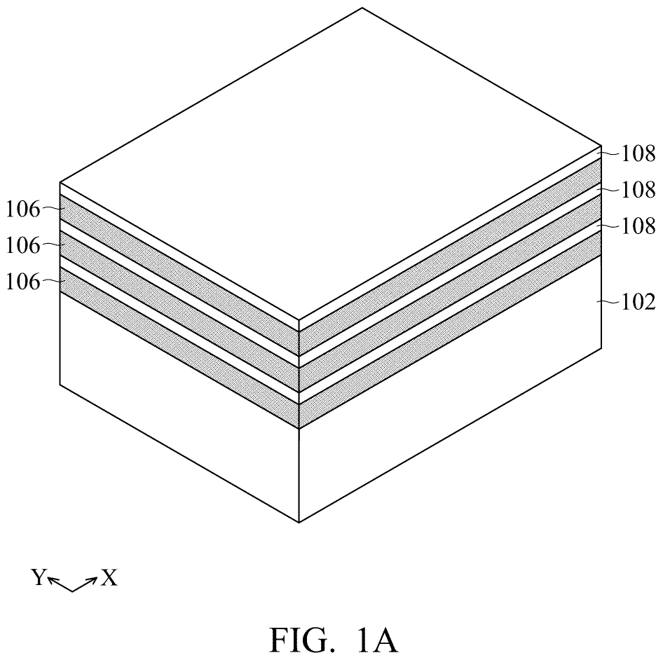

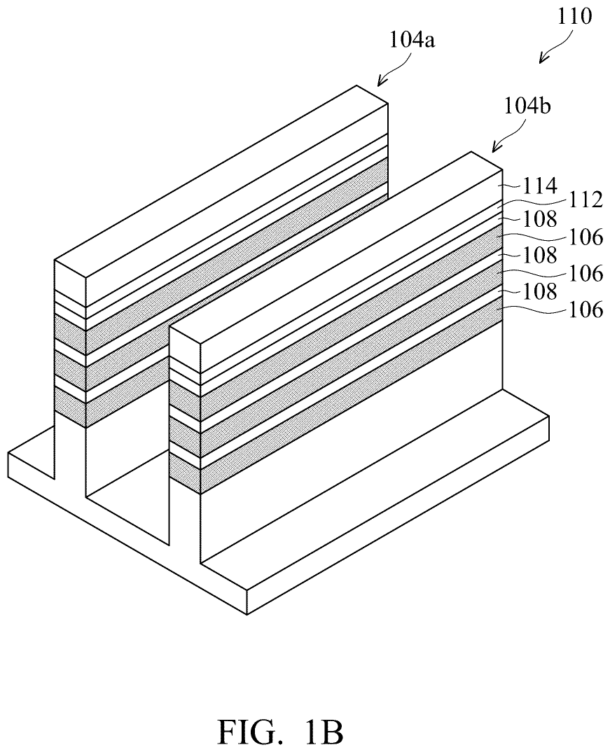

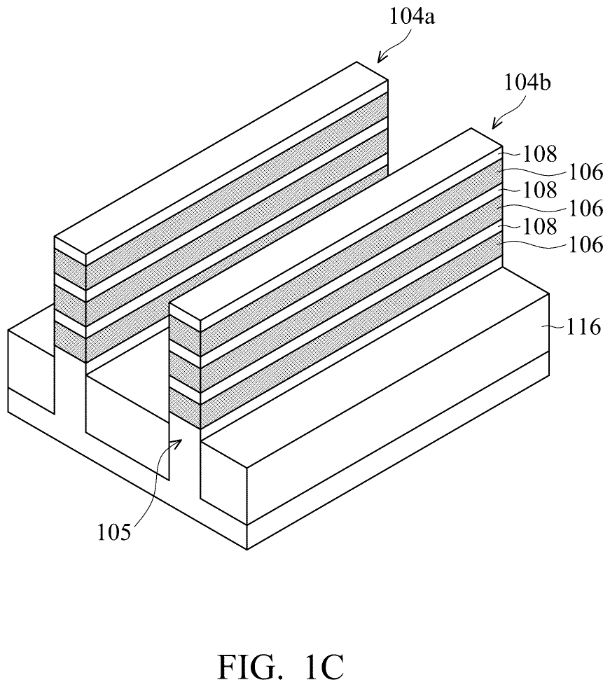

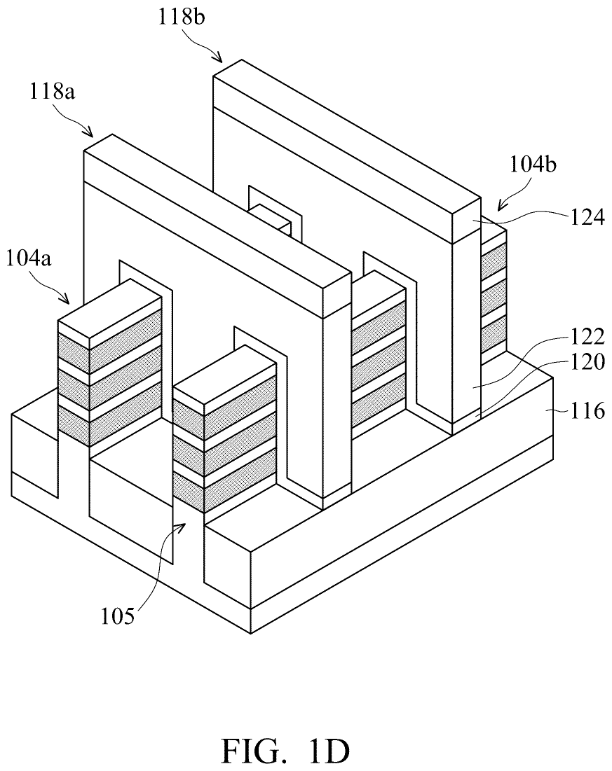

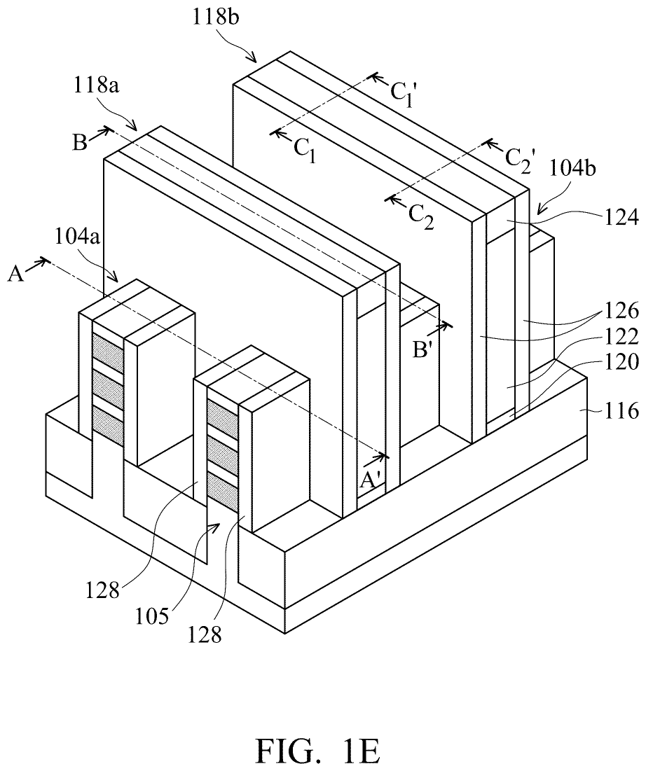

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and the second fin structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

Next, as shown in FIG. 1C, after the first fin structure 104a and the second fin structure 104b is formed, an isolation structure 116 is formed around first fin structure 104a and the second fin structure 104b, and the mask structure 110 is removed, in accordance with some embodiments. The isolation structure 116 is configured to electrically isolate active regions (e.g. the first fin structure 104a and the second fin structure 104b) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, a first dummy gate structure 118a and a second dummy gate structure 118b are formed across the first fin structure 104a and the second fin structure 104b and extend over the isolation structure 116, in accordance with some embodiments. The first dummy gate structure 118a and the second dummy gate structure 118b may be used to define the source/drain (S/D) regions and the channel regions of the resulting semiconductor structure 100a.

In some embodiments, each of the first dummy gate structure 118a and each of the second dummy gate structure 118b includes dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTIO, HfAIO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, the hard mask layers 124 are formed over the first dummy gate structure 118a and the second dummy gate structure 118b. In some embodiments, the hard mask layers 124 include multiple layers, such as an oxide layer and a nitride layer. In some embodiments, the oxide layer is silicon oxide, and the nitride layer is silicon nitride.

The formation of the first dummy gate structure 118a and the second dummy gate structure 118b may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structure 118.

Next, as shown in FIG. 1E, after the first dummy gate structure 118a and the second dummy gate structure 118b are formed, gate spacer layers 126 are formed along and covering opposite sidewalls of the dummy gate structure 118 and fin spacer layers 128 are formed along and covering opposite sidewalls of the source/drain regions of the first fin structure 104a and the second fin structure 104b, in accordance with some embodiments.

The gate spacer layers 126 may be configured to separate source/drain (S/D) structures from the first dummy gate structure 118a, the second dummy gate structure 118b and support the first dummy gate structure 118a, the second dummy gate structure 118b, and the fin space layers 128 may be configured to constrain a lateral growth of subsequently formed source/drain structure and support the first fin structure 104a and the second fin structure 104b.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the first dummy gate structure 118a, the second dummy gate structure 118b, the first fin structure 104a, the second fin structure 104b and the isolation structure 116 over the substrate 102, and performing an anisotropic etching process, such as dry plasma etching, to remove the dielectric layer covering the top surfaces of the first dummy gate structure 118a, the second dummy gate structure 118b, the first fin structure 104a, the second fin structure 104b, and portions of the isolation structure 116.

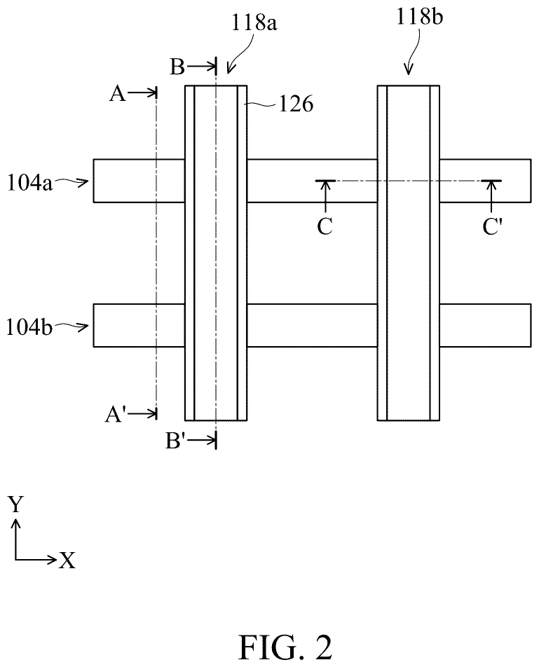

FIG. 2 shows a top-view representation of the semiconductor structure 100a, in accordance with some embodiments.

As shown in FIG. 2, the first fin structure 104a is formed along a first direction (e.g. X-axis), and the second fin structure 104b is formed along the first direction (e.g. X-axis). The first dummy gate structure 118a and the second dummy gate structure 118b are formed along a second direction (e.g. Y-axis). The first dummy gate structure 118a and the second dummy gate structure 118b are formed across the first fin structure 104a and the second fin structure 104b.

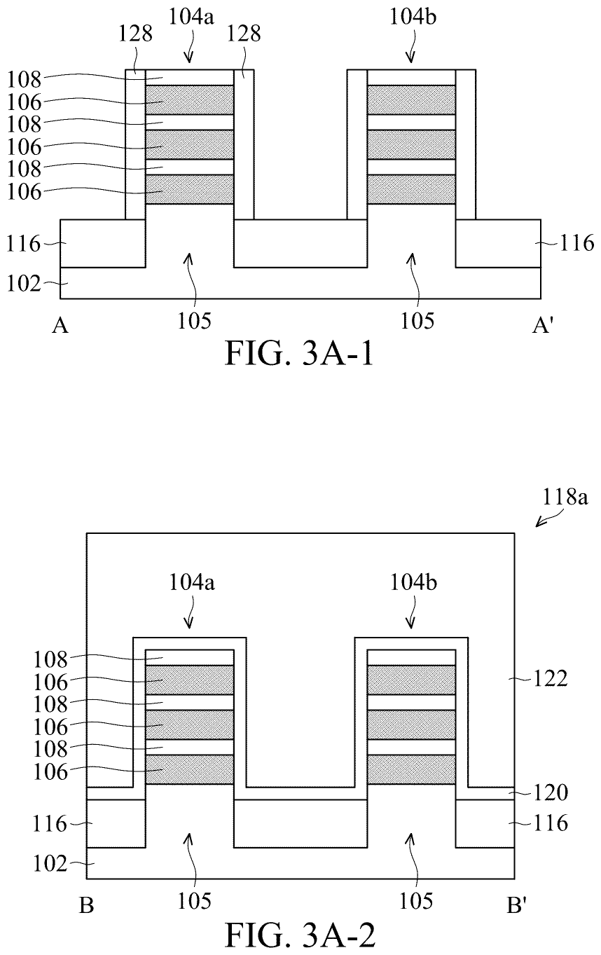

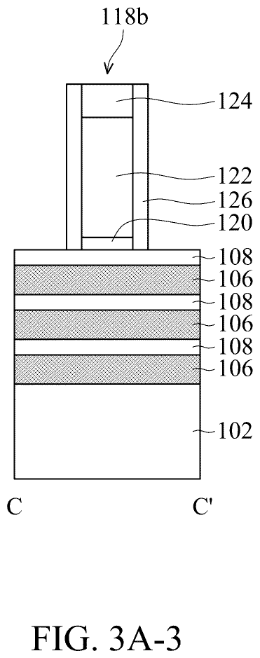

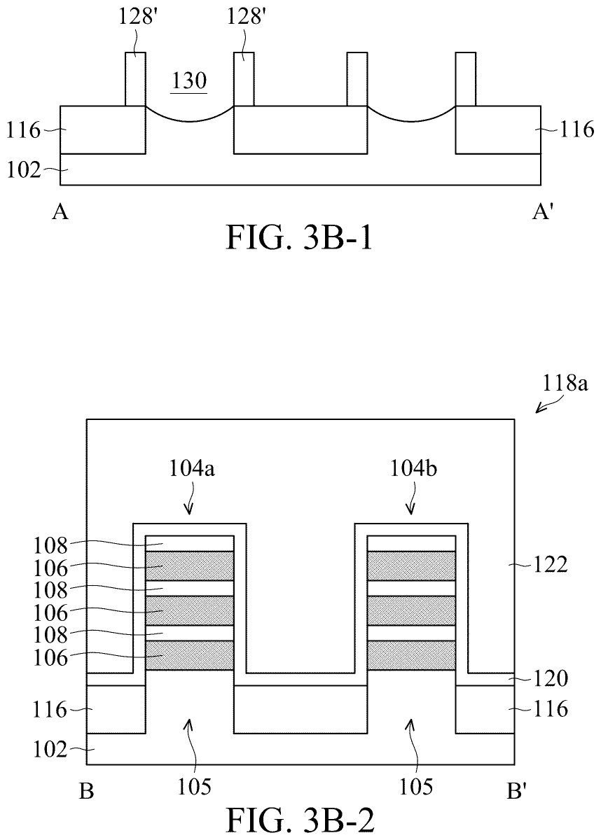

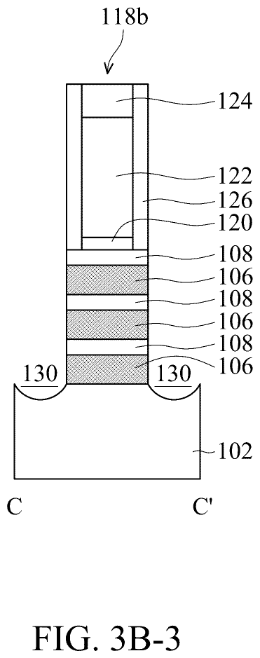

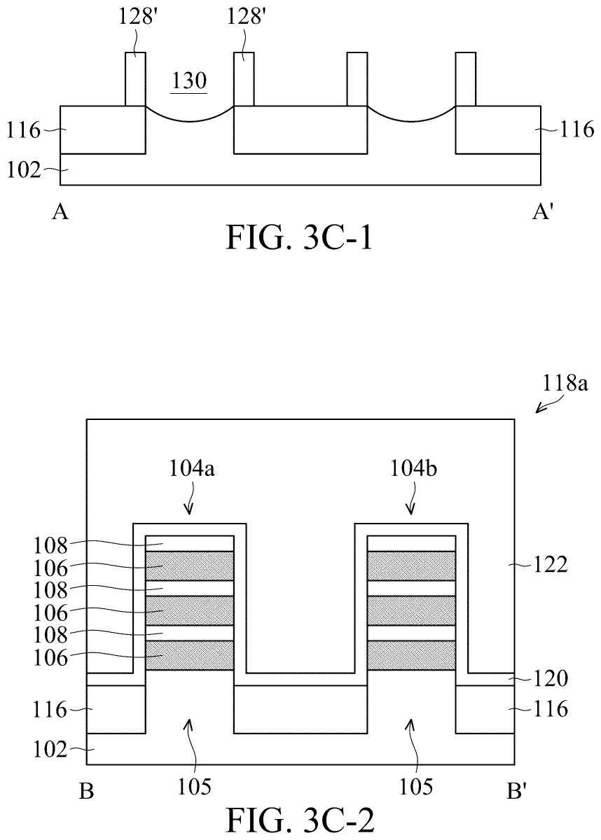

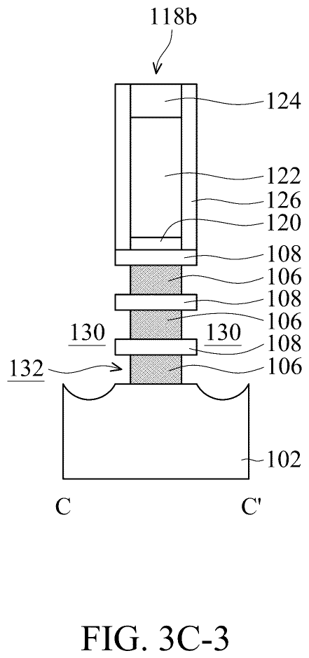

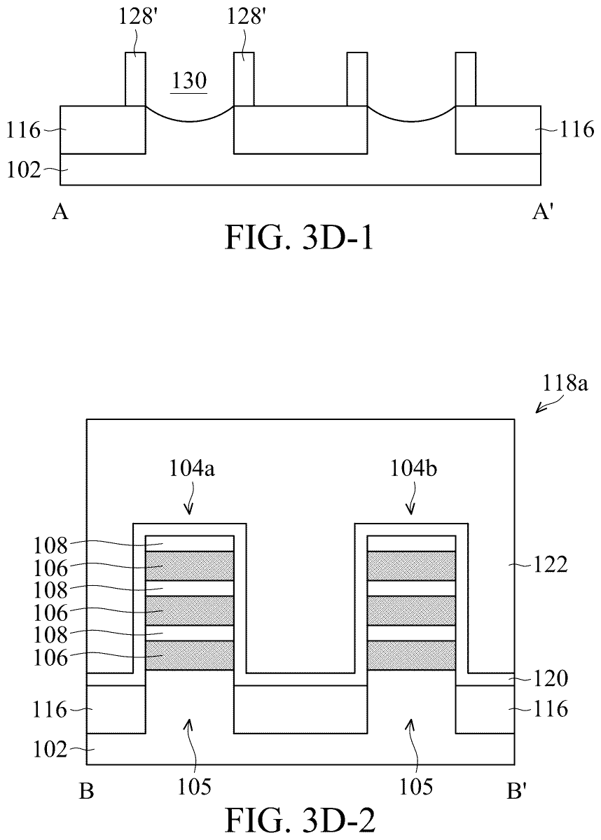

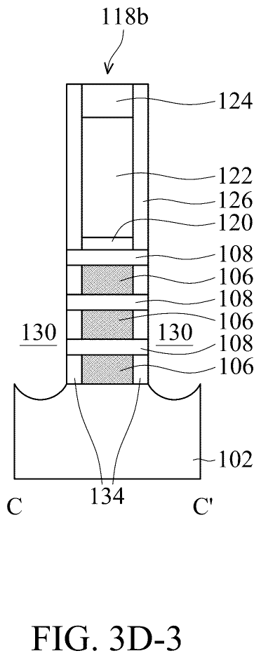

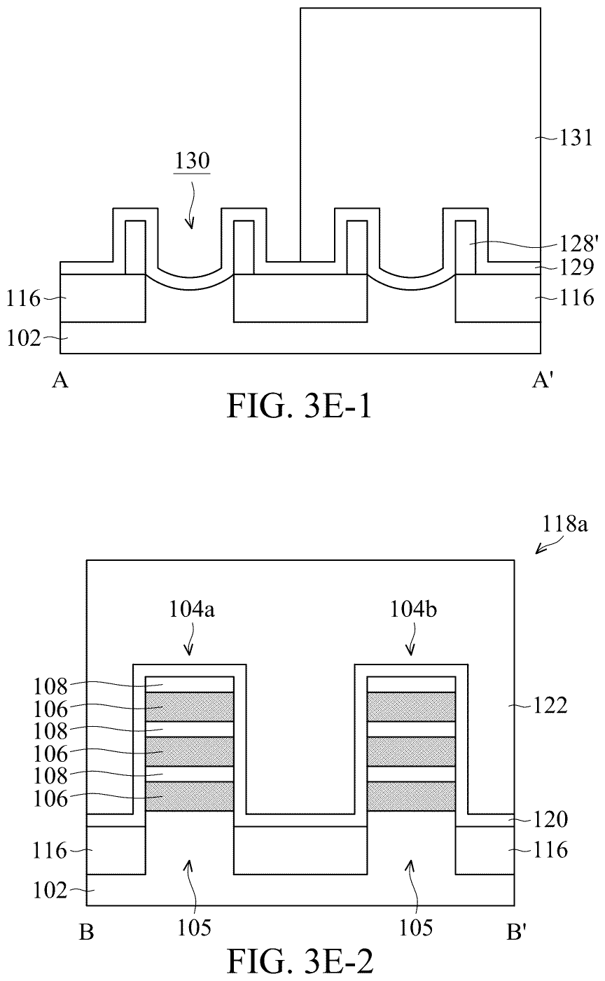

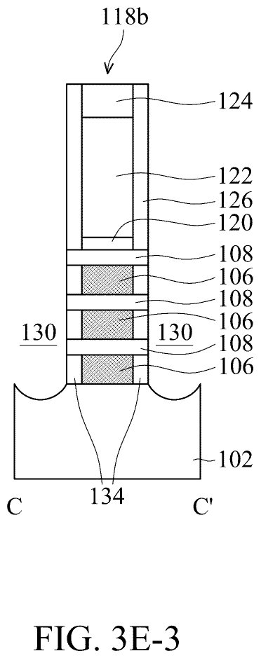

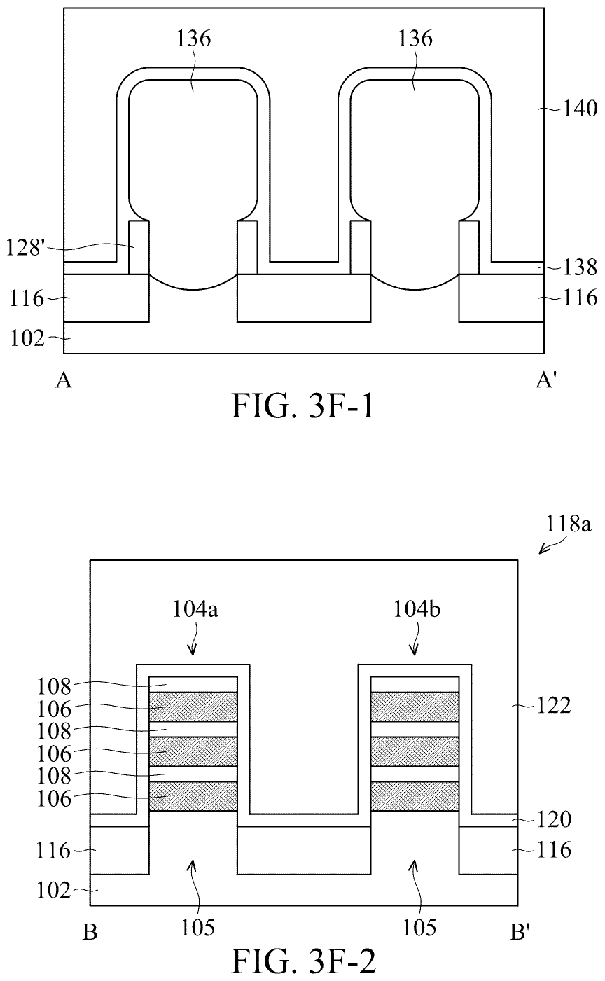

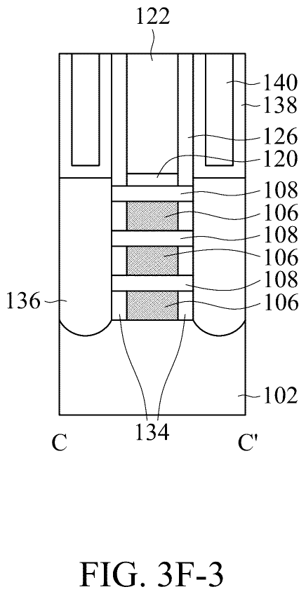

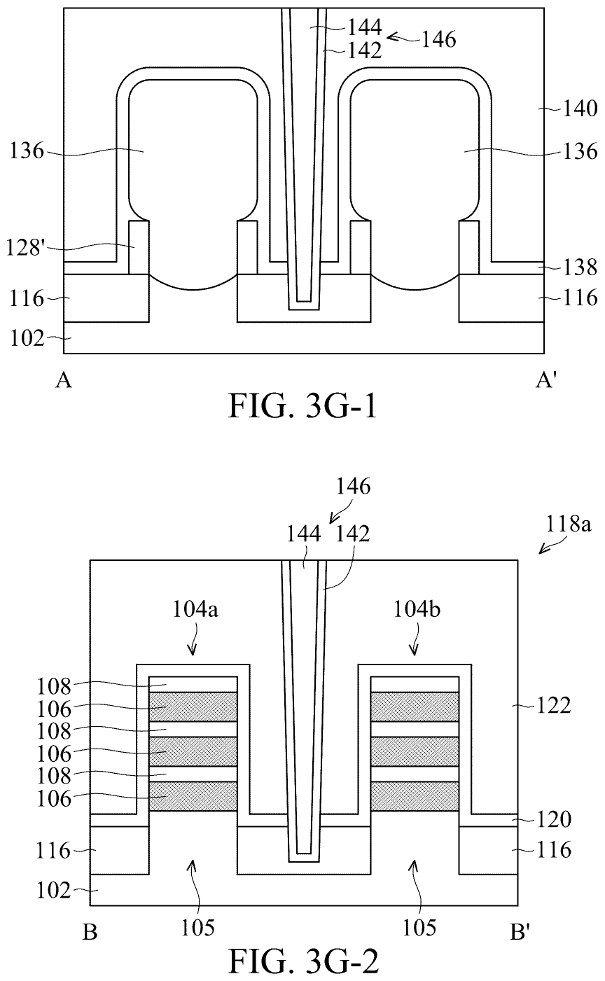

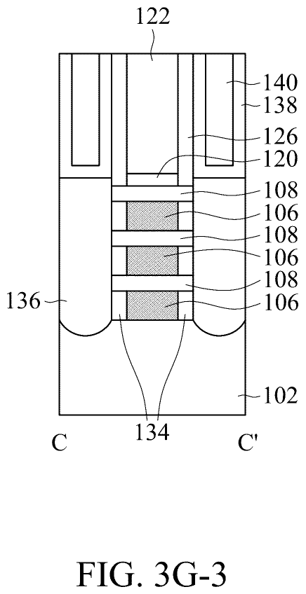

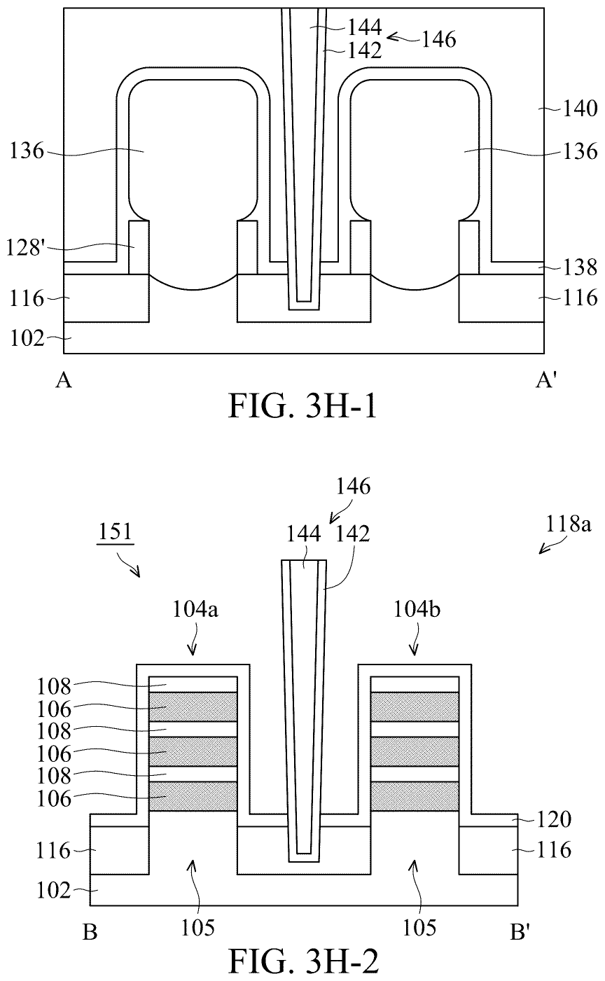

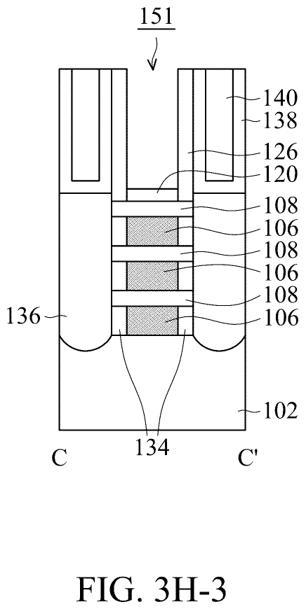

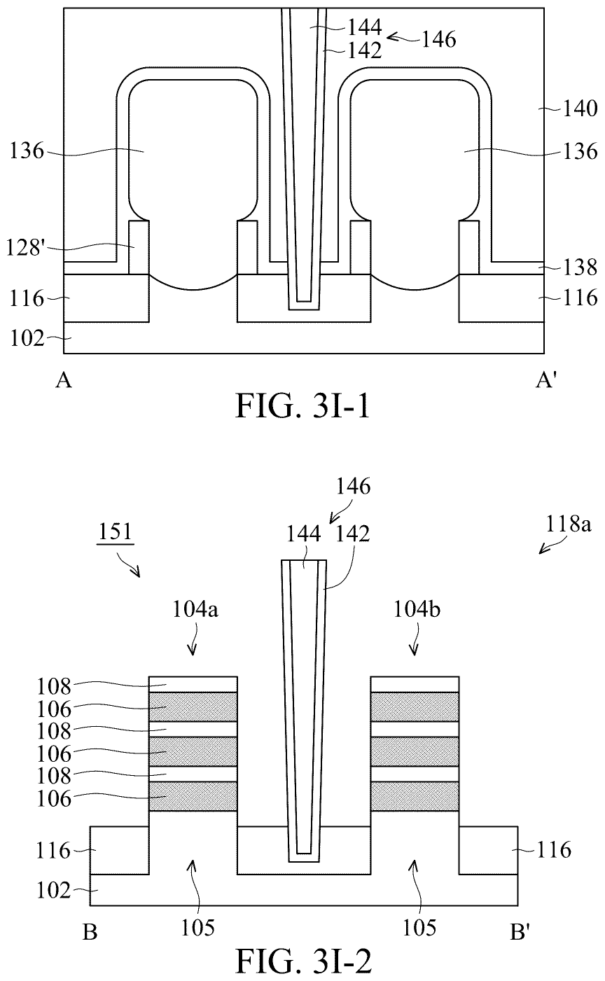

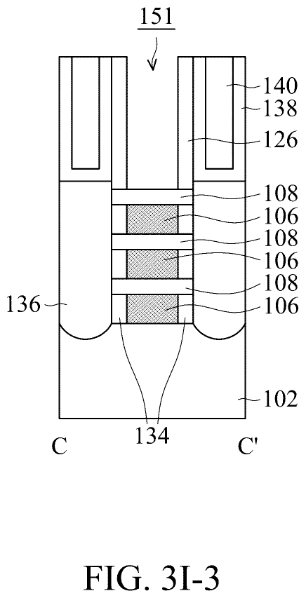

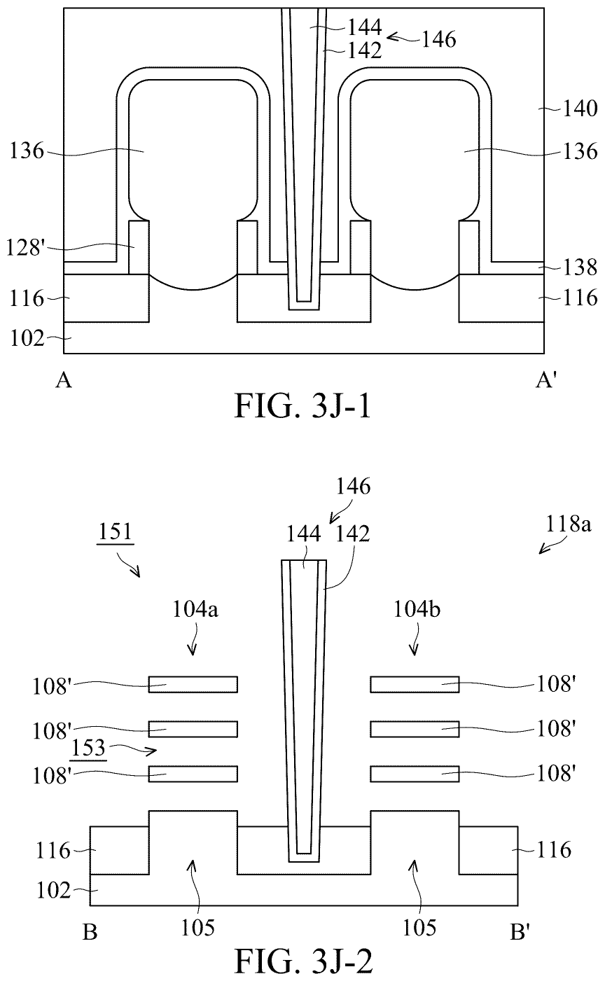

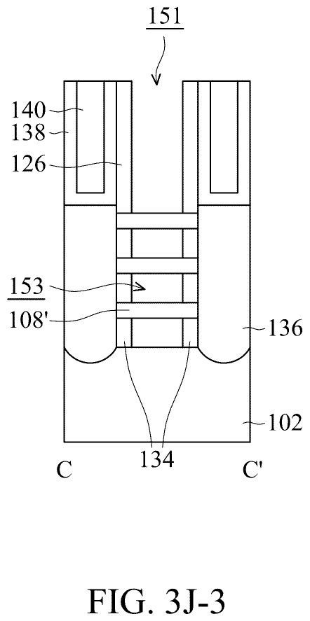

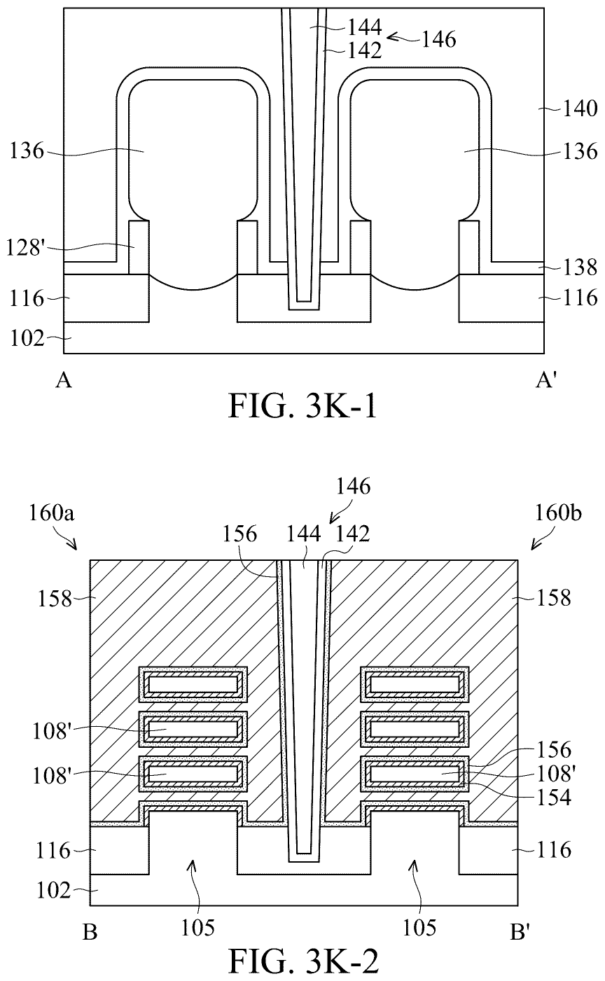

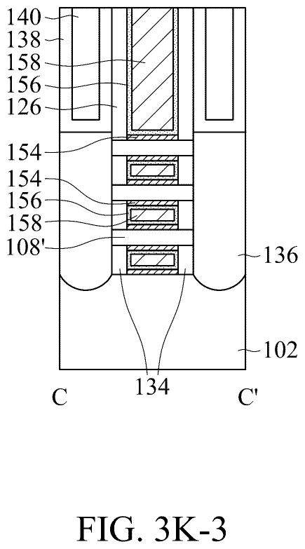

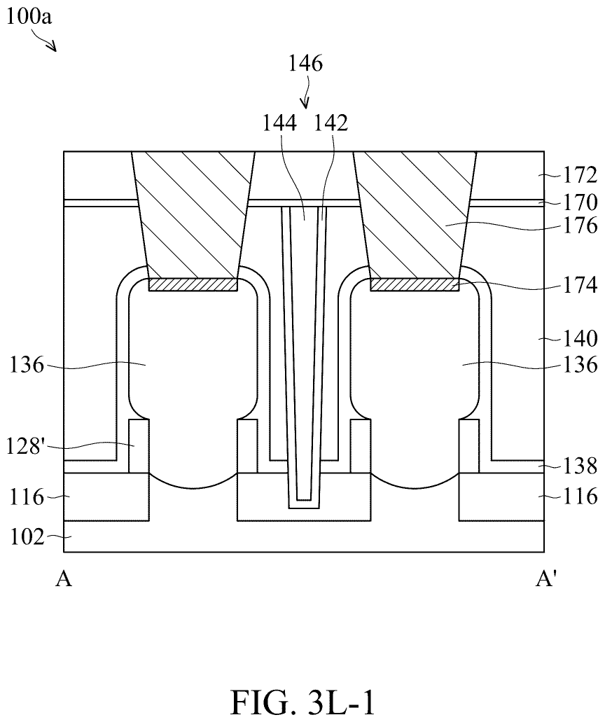

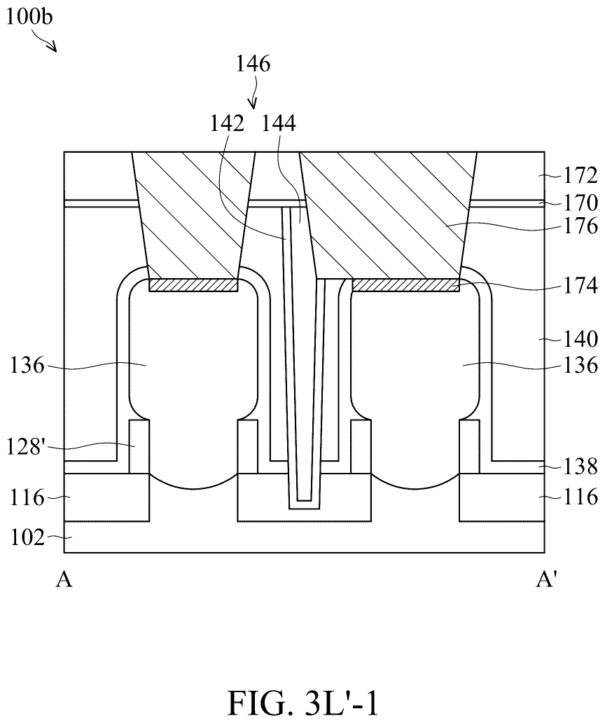

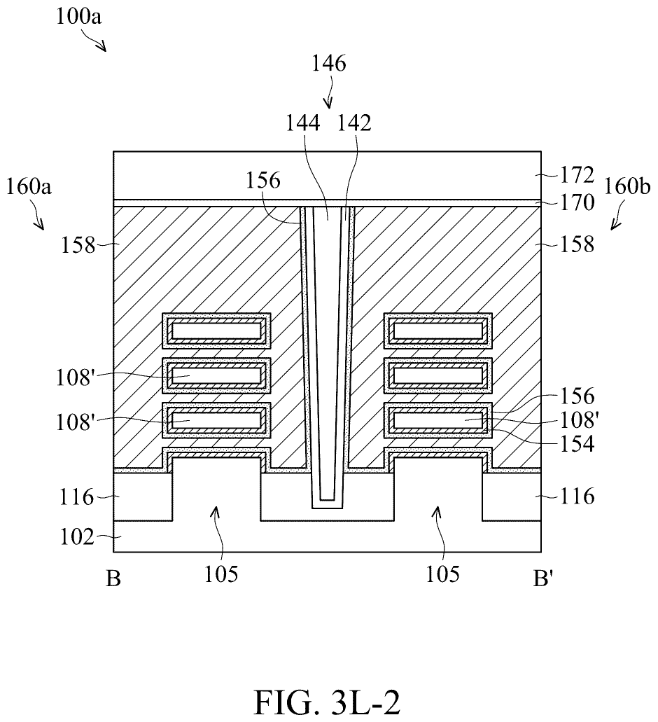

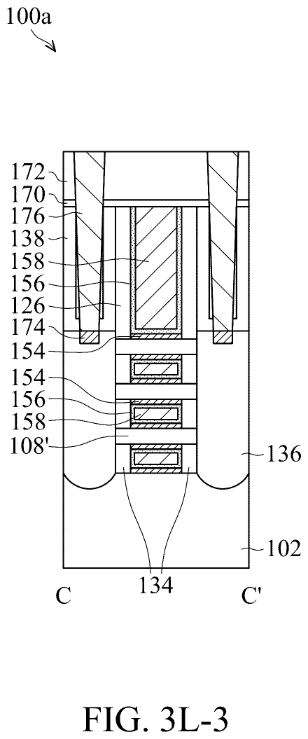

FIGS. 3A-1 to 3L-1 illustrate cross-sectional representations of various stages of manufacturing the semiconductor structure 100a shown along line A-A′ in FIGS. 1E and 1n FIG. 2, in accordance with some embodiments. FIGS. 3A-2 to 3L-2 illustrate cross-sectional representations of various stages of manufacturing the semiconductor structure 100a shown along line B-B′ in FIGS. 1E and 1n FIG. 2, in accordance with some embodiments. FIGS. 3A-3 to 3L-3 illustrate cross-sectional representations of various stages of manufacturing the semiconductor structure 100a shown along line C-C′ in FIGS. 1E and 1n FIG. 2, in accordance with some embodiments.

More specifically, FIG. 3A-1 illustrates the cross-sectional representation shown along line A-A′ ‘in FIG. 1E and FIG. 2. FIG. 3A-2 illustrates the cross-sectional representation shown along line B-B’ in FIG. 1E and FIG. 2 in accordance with some embodiments. FIG. 3A-3 illustrates the cross-sectional representation shown along line C-C′ in FIGS. 1E and 1n FIG. 2.

Next, as shown in FIGS. 3B-1, 3B-2 and 3B-3, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by first dummy gate structure 118a, the second dummy gate structure 118b and the gate spacer layers 126 are removed, in accordance with some embodiments. In addition, some portions of the base fin structure 105 are also recessed to form curved top surfaces, as shown in FIG. 3B-1 in accordance with some embodiments.

In some embodiments, the first fin structure 104a and the second fin structure 104b are recessed by performing an etching process. The etching process may be an anisotropic etching process, such as dry plasma etching, and the first dummy gate structure 118a, the second dummy gate structure 118b and the gate spacer layers 126 are used as etching masks during the etching process. In some embodiments, the fin spacer layers 128 are also recessed to form lowered fin spacer layers 128′.

Afterwards, as shown in FIGS. 3C-1, 3C-2 and 3C-3, after the source/drain (S/D) recesses 130 are formed, the first semiconductor material layers 106 exposed by the source/drain recesses 130 are laterally recessed to form notches 132, in accordance with some embodiments.

In some embodiments, an etching process is performed on the semiconductor structure 100a to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 3D-1, 3D-2 and 3D-3, inner spacer layers 134 are formed in the notches 132 between the second semiconductor material layers 108, in accordance with some embodiments. The inner spacer layers 134 are configured to separate the source/drain (S/D) structures and the gate structures formed in subsequent manufacturing processes in accordance with some embodiments. In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 134 are formed by a deposition process, such as chemical vapor deposition (CVD) process, atomic layer deposition (ALD) process, another applicable process, or a combination thereof.

Afterwards, as shown in FIGS. 3E-1, 3E-2 and 3E-3, after the inner spacer layers 134 are formed, source/drain (S/D) structure 136 are formed in the S/D recesses 130, in accordance with some embodiments.

In some embodiments, the source/drain (S/D) structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structures 136 are made of any applicable material, such as Ge, Si, GaAs, AlGaAs, SiGe, GaAsP, SiP, SiC, SiCP, or a combination thereof.

In some embodiments, the source/drain (S/D) structures 136 are in-situ doped during the epitaxial growth process. For example, the source/drain (S/D) structure 136 may be the epitaxially grown SiGe doped with boron (B). For example, the source/drain (S/D) structure 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain (S/D) structure 136 is doped in one or more implantation processes after the epitaxial growth process

Afterwards, as shown in FIGS. 3F-1, 3F-2 and 3F-3, a contact etch stop layer (CESL) 138 is conformally formed to cover the S/D structures 136, and an interlayer dielectric (ILD) layer 140 is formed over the contact etch stop layers 138, in accordance with some embodiments.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the gate electrode layers 120 of the first dummy gate structure 118a and the second dummy gate structure 118b are exposed, as shown in FIG. 3F-3 in accordance with some embodiments.

Afterwards, as shown in FIGS. 3G-1, 3G-2 and 3G-3, a dielectric wall structure 146 is formed between the two adjacent S/D structures 136, in accordance with some embodiments. In addition, the dielectric wall structure 146 is formed between the first fin structure 104a and the second fin structure 104b. The dielectric wall structure 146 is used to isolate two adjacent S/D structures 136 to reduce the leakage.

The dielectric wall structure 146 includes a liner layer 142 and a filling layer 144 formed on the liner layer 142. The dielectric wall structure 146 is formed by forming a trench (not shown) along the first direction (e.g. x-axis), and the trench is through the ILD layer 140, the CESL 138 (as shown in FIG. 3G-1), the gate spacer layer 126 and the dummy gate electrode layer 122. In addition, as shown in FIG. 3G-2, the trench is further through the dummy gate dielectric layer 120 and the isolation structure 116. Next, the liner layer 142 and the filling layer 144 are formed in the trench.

It should be noted that the bottom surface of the dielectric wall structure 146 is lower than the bottom surface of the S/D structure 136. In some embodiments, there is a distance between the bottom surface of the dielectric wall structure 146 and the bottom surface of the S/D structure 136, and the distance is in a range from about 10 nm to about 200 nm. In addition, the bottom surface of the dielectric wall structure 146 is lower than the bottommost first semiconductor layer 106. The bottom surface of the dielectric wall structure 146 is lower than the top surface of the isolation structure 116. In other words, the top surface of the isolation structure 116 is higher than the bottom surface of the dielectric wall structure 146.

In some embodiments, the liner layer 142 is made of silicon nitride. In some embodiments, the liner layer 142 is formed by a chemical vapor deposition (CVD), a physical vapor deposition, (PVD), an atomic layer deposition (ALD), or other applicable processes. The filling layer 144 may be a single layer or multiple layers. In some embodiments, the filling layer 144 is made of silicon oxide (SiOx), silicon nitride (SiN), silicon carbide (SiC), silicon oxynitride (SiON), silicon carbon nitride (SiCN), silicon oxide carbonitride (SiOCN), and/or a combination thereof. In some embodiments, the filling layer 144 is formed by a chemical vapor deposition (CVD), a physical vapor deposition, (PVD), an atomic layer deposition (ALD), or other applicable processes.

Next, as shown in FIGS. 3H-1, 3H-2 and 3H-3, the dummy gate electrode layer 122 is removed to form a trench 151, in accordance with some embodiments.

The dummy gate electrode layer 122 is removed by one or more etching processes. For example, when the dummy gate electrode layer 122 is polysilicon, a wet etchant such as a tetramethylammonium hydroxide (TMAH) solution may be used to selectively remove the dummy gate electrode layer 122.

Afterwards, as shown in FIGS. 3I-1, 3I-2 and 3I-3, the dummy gate dielectric layer 120 is removed to expose the first fin structure 104a and the second fin structure 104b, in accordance with some embodiments.

In some embodiments, the dummy gate dielectric layer 120 is removed by using a plasma dry etching, a dry chemical etching, and/or a wet etching.

Next, as shown in FIGS. 3J-1, 3J-2 and 3J-3, the first semiconductor material layers 106 are removed to form nanostructures 108′ (or channel layers 108′) with the second semiconductor material layers 108, in accordance with some embodiments. As a result, gaps 153 are formed adjacent to the nanostructures 108′ (or channel layers 108′).

Afterwards, as shown in FIGS. 3K-1, 3K-2 and 3K-3, after the nanostructures 108′ are formed, the interfacial layer 154, the gate dielectric layer 156, and the gate electrode layer 158 are formed in the trench 151 and the gaps 153, in accordance with some embodiments.

After the interfacial layers 154, the gate dielectric layers 156, and the gate electrode material are formed, a planarization process such as CMP or an etch-back process may be performed. After the planarization process, the gate electrode layer 158 is divided into two portions by the dielectric wall structure 146 to form a first gate structure 160a and a second gate structure 160b.

After the nanostructures 108′ are formed, the first gate structure 160a and the second gate structure 160b are formed wrapped around the nanostructures 108′. The first gate structure 160a and the second gate structure 160b wrap around the nanostructures 108′ to form gate-all-around transistor structures, in accordance with some embodiments. In some embodiments, the first gate structure 160a includes the interfacial layer 154, the gate dielectric layer 156, and the gate electrode layer 158. In some embodiments, the second gate structure 160b includes the interfacial layer 154, a gate dielectric layer 156, and the gate electrode layer 158.

In some embodiments, the interfacial layers 154 are oxide layers formed around the nanostructures 108′ and on the top of the base fin structure 105. In some embodiments, the interfacial layers 154 are formed by performing a thermal process.

In some embodiments, the gate dielectric layers 156 are formed over the interfacial layers 154, so that the nanostructures 108′ are surrounded (e.g. wrapped) by the gate dielectric layers 156. In addition, the gate dielectric layers 156 also cover the sidewalls of the gate spacer layers 126 and the inner spacer layers 134 in accordance with some embodiments. In some embodiments, the gate dielectric layers 156 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layers 156 are formed using chemical vapor deposition (CVD), atomic layer deposition (ALD), another applicable method, or a combination thereof.

In some embodiments, the first gate structure 160a and the second gate structure 160b are formed on the gate dielectric layer 156. In some embodiments, the first gate structure 160a and the second gate structure 160b are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

In some embodiments, the first gate structure 160a and the second gate structure 160b are formed using chemical vapor deposition (CVD), atomic layer deposition (ALD), electroplating, another applicable method, or a combination thereof. Other conductive layers, such as work function metal layers, may also be formed in the first gate structure 160a and the second gate structure 160b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

Next, as shown in FIGS. 3L-1, 3L-2 and 3L-3, an etch stop layer 170 is formed over the gate structure 142, and a dielectric layer 172 is formed over the etch stop layer 170, in accordance with some embodiments.

In some embodiments, the etch stop layer 170 is made of a dielectric materials, such as silicon nitride, silicon oxide, silicon oxynitride, another suitable dielectric material, or a combination thereof. The dielectric material for the etch stop layers 170 may be conformally deposited over the semiconductor structure by performing chemical vapor deposition (CVD), ALD, other application methods, or a combination thereof.

The dielectric layer 172 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 172 may be formed by chemical vapor deposition (CVD), physical vapor deposition, (PVD), atomic layer deposition (ALD), or other applicable processes.

Next, a silicide layer 174 and an S/D contact structure 176 are formed over the S/D structure 136, in accordance with some embodiments. In some embodiments, the contact openings may be formed through the contact etch stop layer 138, the interlayer dielectric layer 140, the etch stop layer 170 and the dielectric layer 172 to expose the top surfaces of the S/D structures 136, and then the silicide layers 174 and the S/D contact structure 176 may be formed in the contact openings. The contact openings may be formed using a photolithography process and an etching process. In addition, some portions of the S/D structure 136 exposed by the contact openings may also be etched during the etching process.

The silicide layers 174 may be formed by forming a metal layer over the top surfaces of the S/D structure 136 and annealing the metal layer so the metal layer reacts with the S/D structure 136 to form the silicide layers 174. The unreacted metal layer may be removed after the silicide layers 174 are formed.

The S/D contact structure 176 may include a barrier layer and a conductive layer. In some other embodiments, the S/D contact structure 176 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

It should be noted that the two adjacent S/D structures 136 are isolated or separated from the dielectric wall structure 146, and the unwanted connection between the two adjacent S/D structures 136 is prevented. Therefore, the unwanted leakage of the semiconductor structure 100a is reduced, and the performance of the semiconductor structures 100a is improved. In addition, the dielectric wall structure 146 extends from the S/D region to the gate region, and it can be a barrier wall between two adjacent S/D structures 136 and can divide or cut the gate electrode layer 158 into two portions.

FIG. 3L′-1 illustrates a cross-sectional representation of a semiconductor structure 100b, in accordance with some embodiments. The semiconductor structure 100b of FIG. 3L′-1 includes elements that are similar to, or the same as, elements of the semiconductor structure 100a of FIG. 3L-1.

FIG. 3L′-1 is are similar to, or the same as, FIG. 3L-1, the difference between FIG. 3L′-1 and FIG. 3L is that the S/D contact structure 176 is in direct contact with the dielectric wall structure 146. More specially, a portion of the dielectric wall structure 146 is removed to form a trench and a portion of the S/D contact structure 176 is formed in the trench. The portion of the S/D contact structure 176 is embedded in the dielectric wall structure 146.

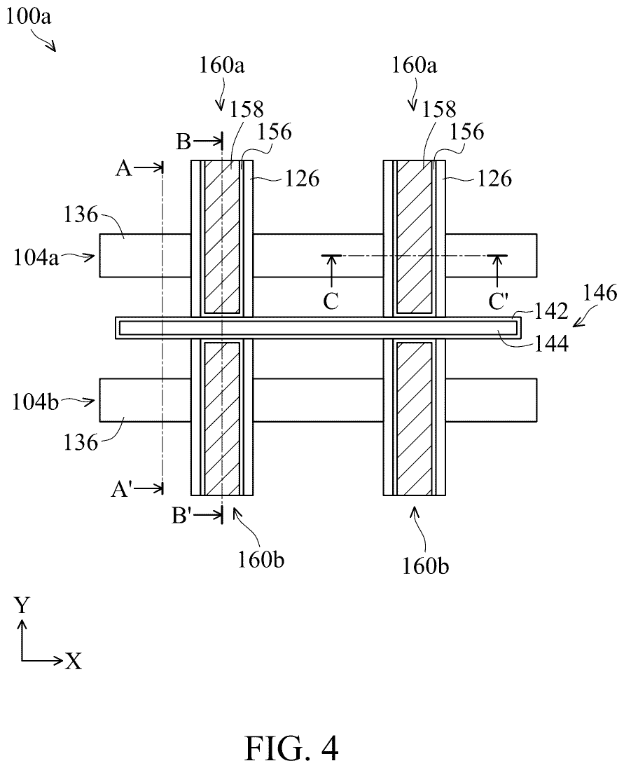

FIG. 4 shows a top-view representation of the semiconductor structure 100a after forming the dielectric wall structure 146, in accordance with some embodiments. FIG. 3L-1 illustrates the cross-sectional representation shown along line A-A′ ‘in FIG. 4. FIG. 3L-2 illustrates the cross-sectional representation shown along line B-B’ in FIG. 4, in accordance with some embodiments. FIG. 3L-3 illustrates the cross-sectional representation shown along line C-C′ in FIG. 4.

As shown in FIG. 4, the dielectric wall structure 146 is formed along the second direction (e.g. y-axis). The dielectric wall structure 146 has a first portion, a second portion and a third portion. The first portion is between the S/D structure 136 and another S/D structure 136. The second portion is between two adjacent gate spacer layers 126. The third portion is between the first gate structure 160a and the second gate structure 160b.

As shown in FIG. 4, since the gate dielectric layer 156 is formed after the dielectric wall structure 146 is formed, and the gate dielectric layer 156 is formed along the sidewall surface of the dielectric wall structure 146 when seen from a top-view. In some embodiments, the gate dielectric layer 156 has a U-shaped structure when seen from a top-view. In some embodiments, the dielectric wall structure 146 has a rectangular structure when seen from a top-view.

The dielectric wall structure 146 is a continuous structure and extends from the S/D region to the gate region. The dielectric wall structure 146 can be used as the barrier wall between two adjacent S/D structures 136 to reduce the leakage. Furthermore, the dielectric wall structure 146 can also be used as the barrier layer between two adjacent gate structures 160a, 160b to divide the gate structures 160. By forming the dielectric wall structure 146 between two adjacent S/D structures 136, the unwanted connection between two adjacent S/D structures 136 is prevented. Therefore, the leakage issue of the semiconductor structure 100a is reduced and the performance of the semiconductor structure 100a is improved.

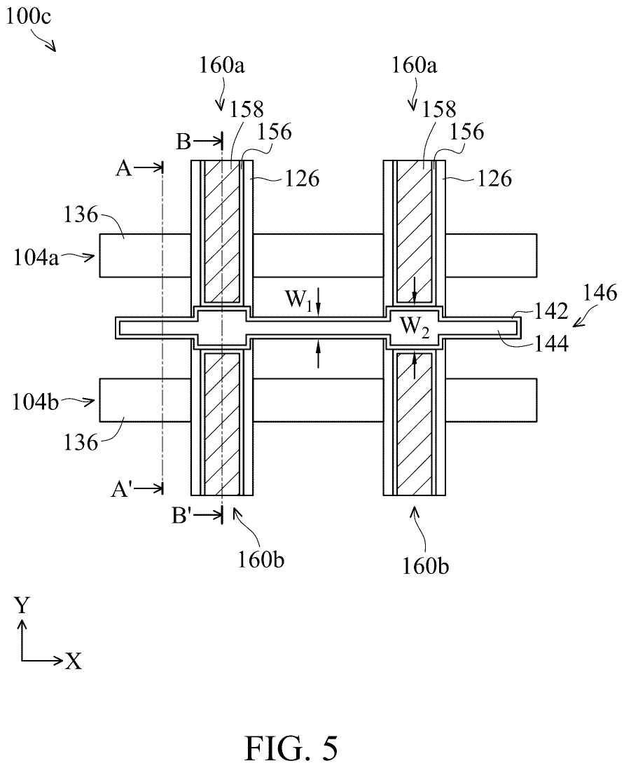

FIG. 5 shows a top-view representation of a semiconductor structure 100c, in accordance with some embodiments. FIG. 5 includes elements that are similar to, or the same as, elements of the semiconductor structure 100a of FIG. 4.

As shown in FIG. 5, the dielectric wall structure 146 has a cross-like shape structure when seen from a top-view. The dielectric wall structure 146 does not have uniform width along the second direction (e.g. y-axis).

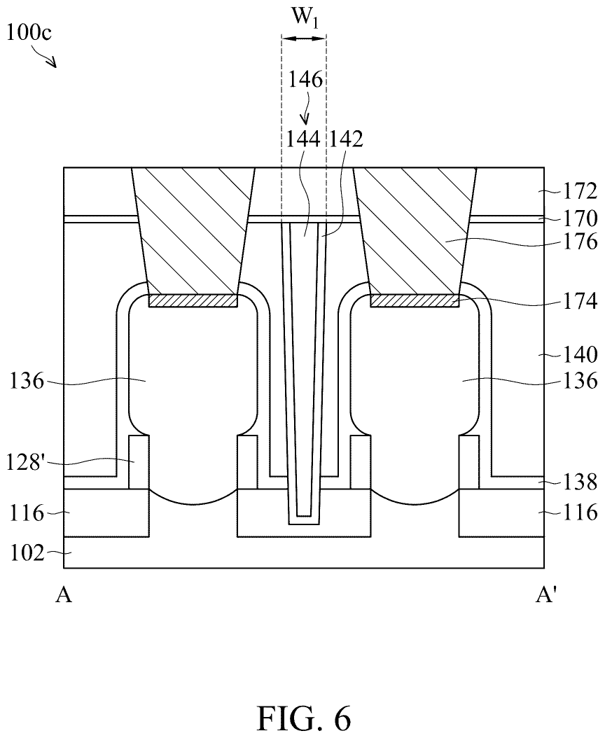

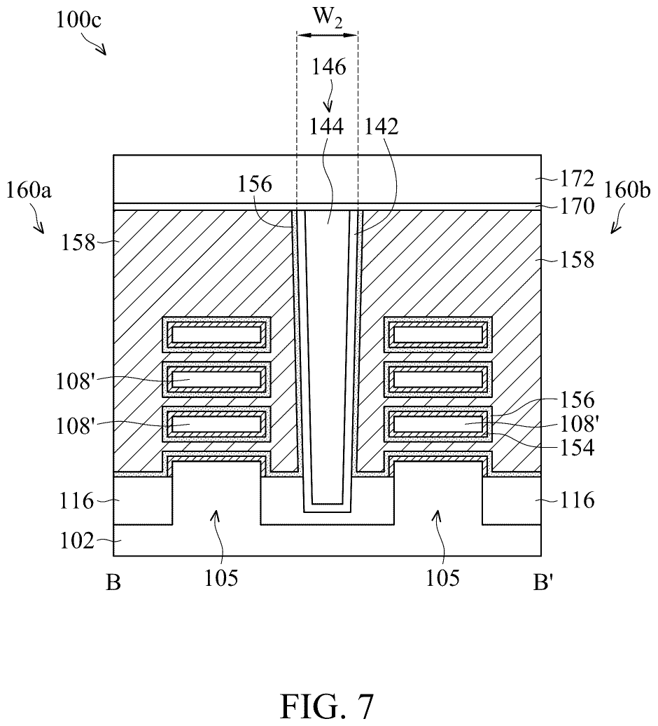

FIG. 6 illustrates a cross-sectional representation of the semiconductor structure 100c shown along line A-A′ in FIG. 5, in accordance with some embodiments. FIG. 7 illustrates a cross-sectional representation of the semiconductor structure 100c shown along line B-B′ in FIG. 5, in accordance with some embodiments.

As shown in FIGS. 5, 6 and 7, the first portion of the dielectric wall structure 146 between two adjacent S/D structures 136 has a first width W₁ along the second direction. The second portion of the dielectric wall structure 146 between the first gate structure 160a and the second gate structure 160b has a second width W₂ along the second direction. In some embodiments, the first width W₁ of the first portion of the dielectric wall structure 146 is smaller than the second width W₂ of the second portion of the dielectric wall structure 146. In some embodiments, the difference between the first width W₁ and the second width W₂ is in a range from about 2 nm to about 40 nm.

FIGS. 8A-1 to 8E-1 illustrate cross-sectional representations of various stages of manufacturing a semiconductor structure 100d shown along line A-A′ in FIGS. 1E and 1n FIG. 2, in accordance with some embodiments. FIGS. 8A-2 to 8E-2 illustrate cross-sectional representations of various stages of manufacturing the semiconductor structure 100a shown along line B-B′ in FIGS. 1E and 1n FIG. 2, in accordance with some embodiments. FIGS. 8A-3 to 8E-3 illustrate cross-sectional representations of various stages of manufacturing the semiconductor structure 100a shown along line C-C′ in FIGS. 1E and 1n FIG. 2, in accordance with some embodiments.

The semiconductor structure 100d as shown in FIGS. 8A-1, 8A-2 and 8A-3 is similar to the semiconductor structure 100a as shown in FIGS. 3F-1, 3F-2 and 3F-3.

Next, as shown in FIGS. 8B-1, 8B-2 and 8B-3, the dummy gate electrode layer 122 is removed to form the trench 151, and then the dummy gate dielectric layer 120 is removed, in accordance with some embodiments. Next, the first semiconductor material layers 106 are removed to form nanostructures 108′ (or channel layers 108′). The gaps 153 are formed between two adjacent second semiconductor layers 108.

Afterwards, as shown in FIGS. 8C-1, 8C-2 and 8C-3, after the nanostructures 108′ are formed, the interfacial layer 154, the gate dielectric layer 156, and the gate electrode layer 158 are formed in the trench 151 and the gaps 153, in accordance with some embodiments.

Next, as shown in FIGS. 8D-1, 8D-2 and 8D-3, the dielectric wall structure 146 is formed between two adjacent S/D structures 136, and divides or cuts the gate electrode layer 158 into two portions, in accordance with some embodiments. As a result, the first gate structure 160a is isolated from the second gate structure 160b by the dielectric wall structure 146.

Afterwards, as shown in FIGS. 8E-1, 8E-2 and 8E-3, the etch stop layer 170 is formed over the gate structure 142, and the dielectric layer 172 is formed over the etch stop layer 150, in accordance with some embodiments. Next, the silicide layer 174 and an S/D contact structure 176 are formed over the S/D structure 136. The S/D structure 136 is electrically connected to the S/D contact structure 176.

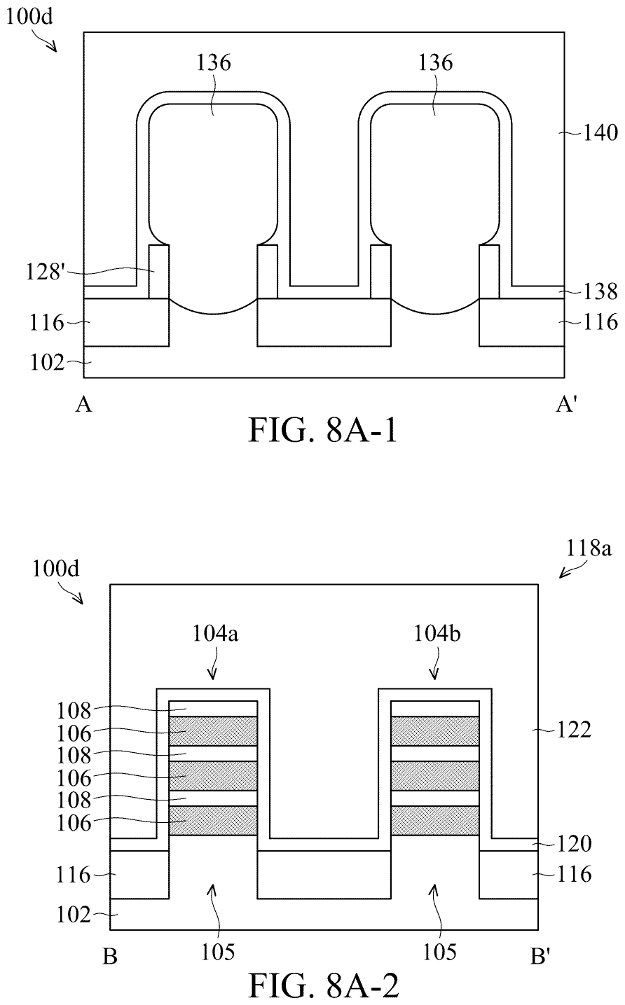

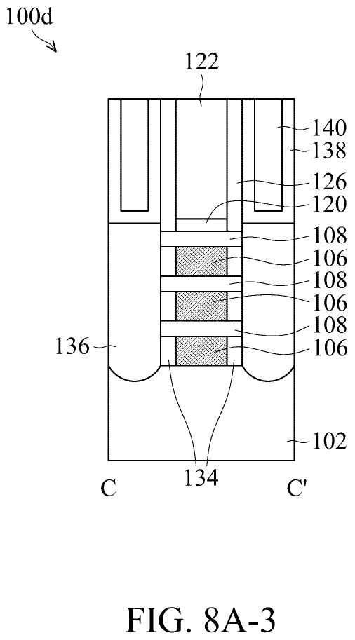

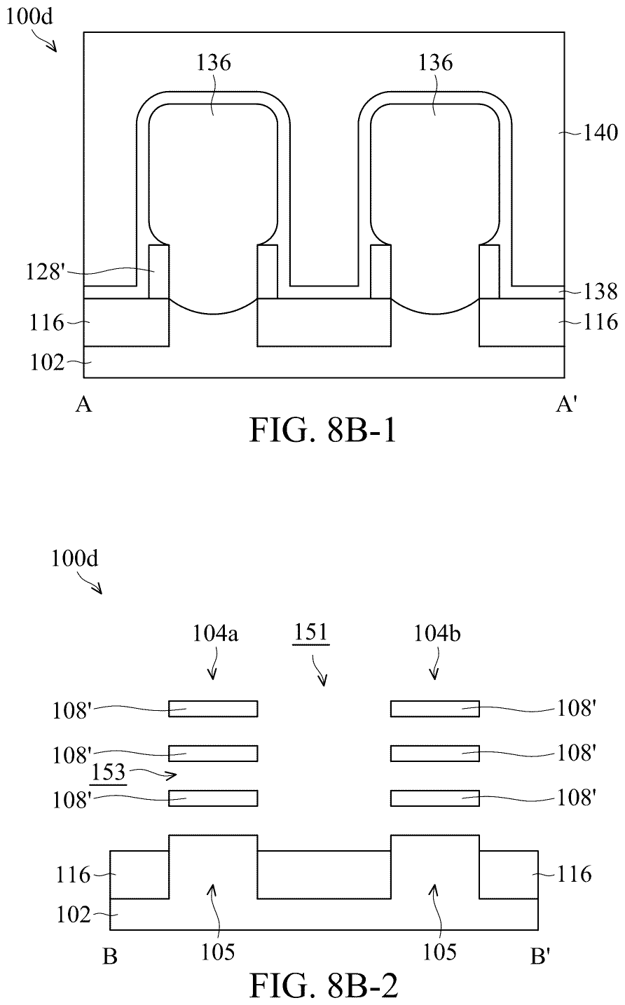

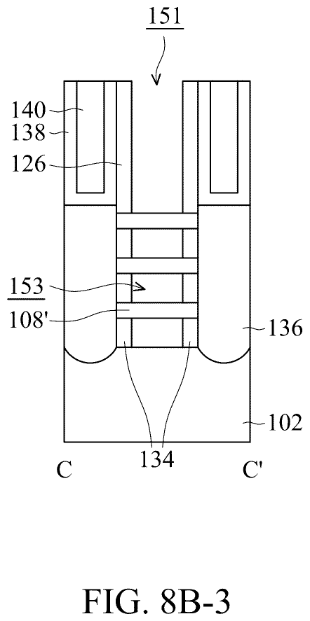

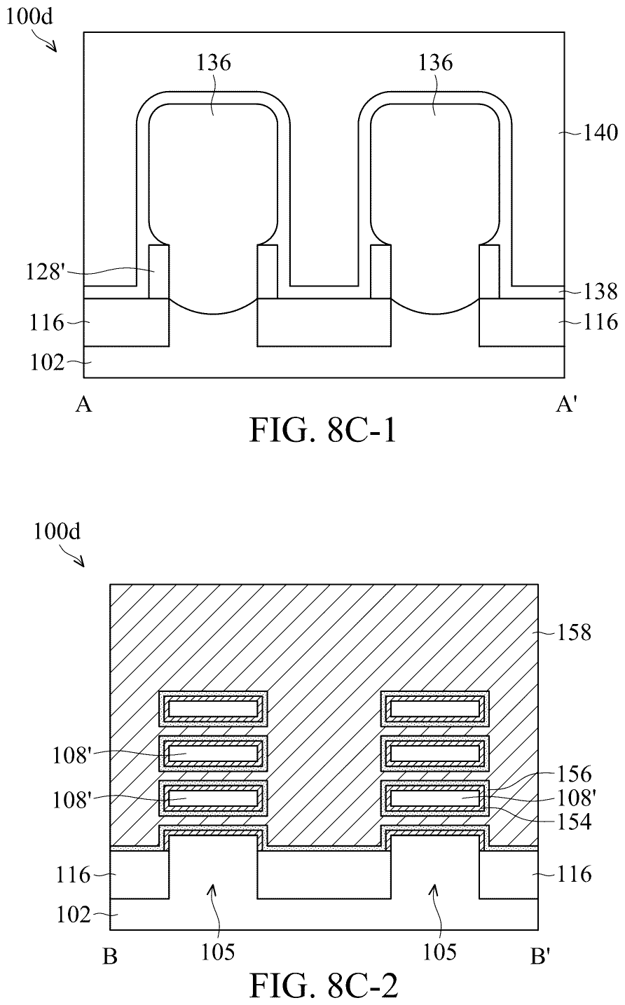

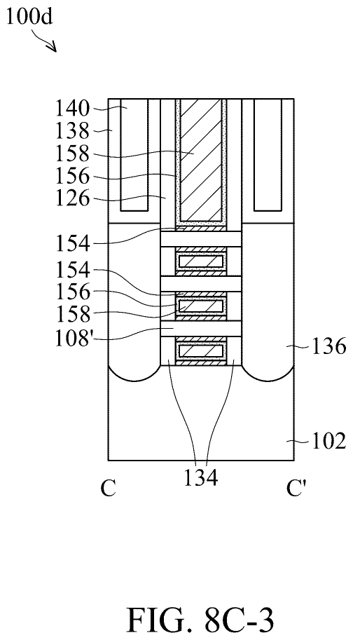

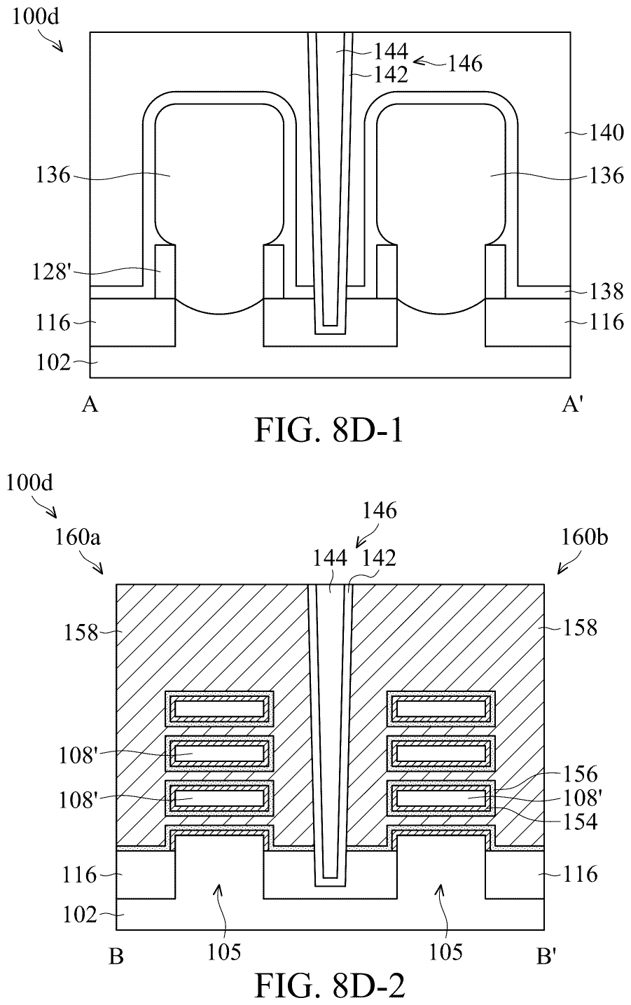

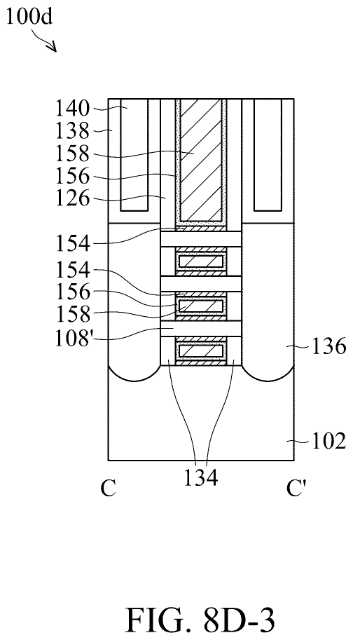

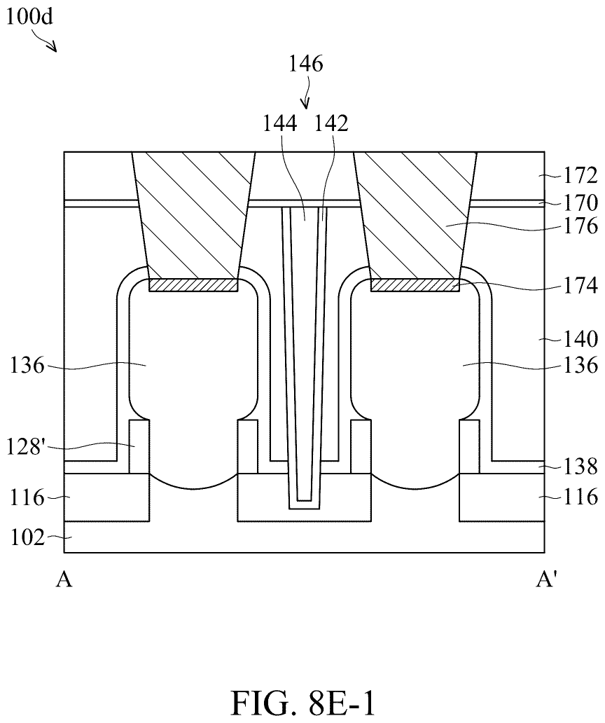

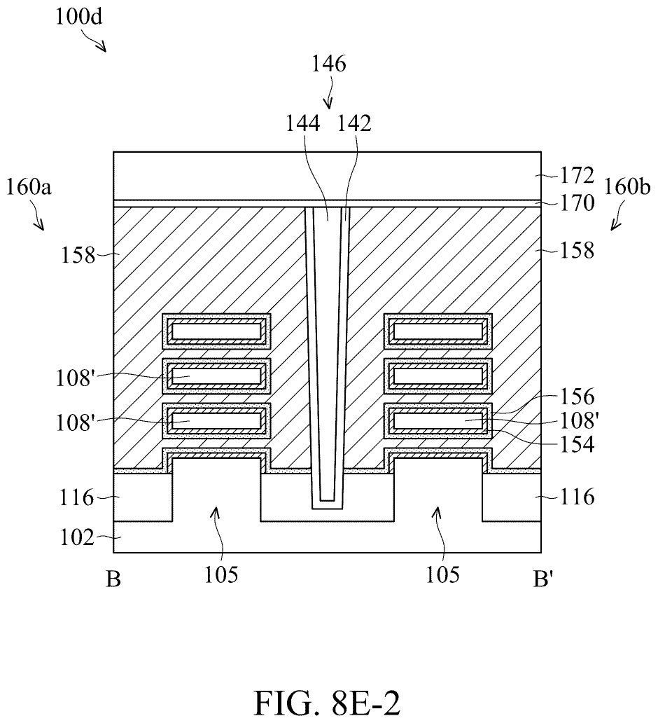

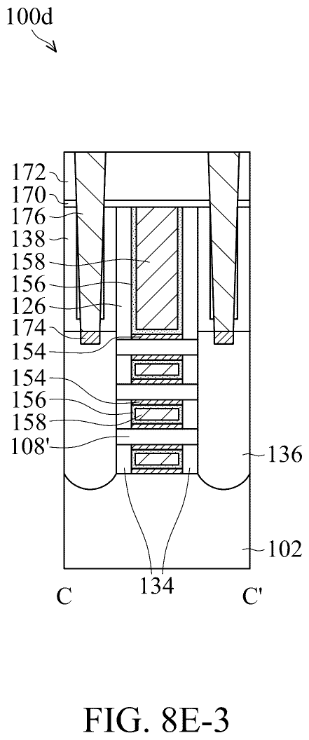

FIG. 9 shows a top-view representation of the semiconductor structure 100d after forming the dielectric wall structure 146, in accordance with some embodiments. FIG. 8E-1 illustrates the cross-sectional representation shown along line A-A′ ‘in FIG. 9. FIG. 8E-2 illustrates the cross-sectional representation shown along line B-B’ in FIG. 9, in accordance with some embodiments. FIG. 8E-3 illustrates the cross-sectional representation shown along line C-C′ in FIG. 9.

As shown in FIG. 9, the dielectric wall structure 146 is formed along the second direction (e.g. y-axis). The dielectric wall structure 146 has a first portion, a second portion and a third portion. The first portion is between the S/D structure 136 and another S/D structure 136. The second portion is between two adjacent gate spacer layers 126. The third portion is between the first gate structure 160a and the second gate structure 160b.

It should be noted, since the gate dielectric layer 156 is formed before the dielectric wall structure 146 is formed, and the shape of the gate dielectric layer 156 shown in FIG. 9 is different from the shape of gate dielectric layer 156 (with U-shaped structure) shown in FIG. 4.

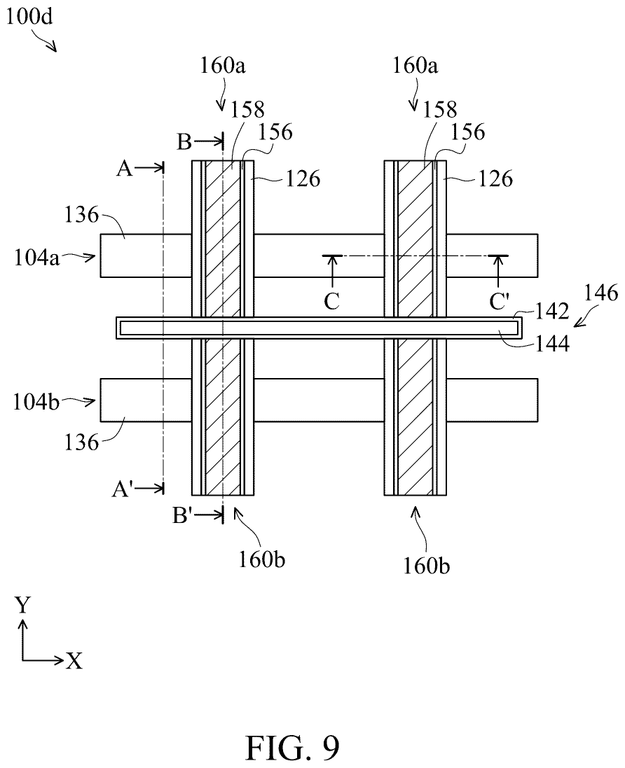

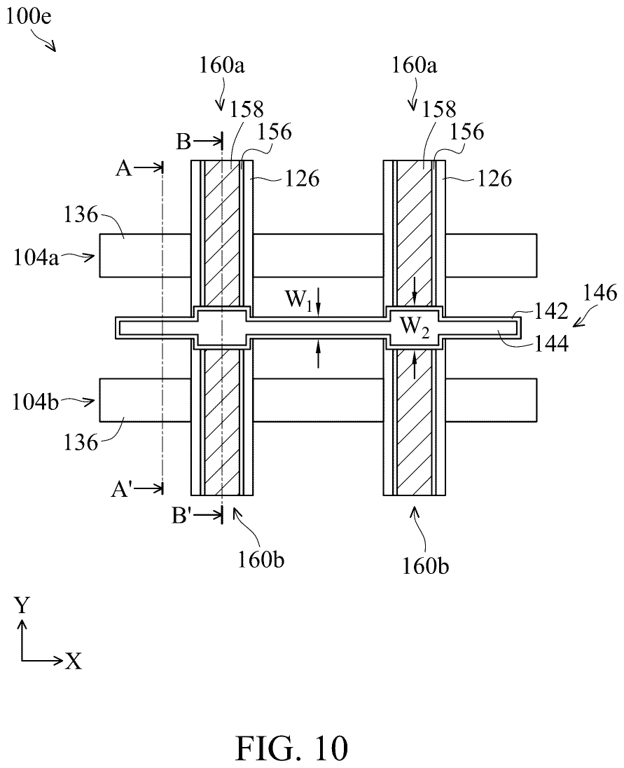

FIG. 10 shows a top-view representation of a semiconductor structure 100e, in accordance with some embodiments. FIG. 10 includes elements that are similar to, or the same as, elements of the semiconductor structure 100d of FIG. 9.

As shown in FIG. 10, the dielectric wall structure 146 has a cross-shaped structure when seen from a top-view. The dielectric wall structure 146 does not have uniform width along the second direction (e.g. y-axis).

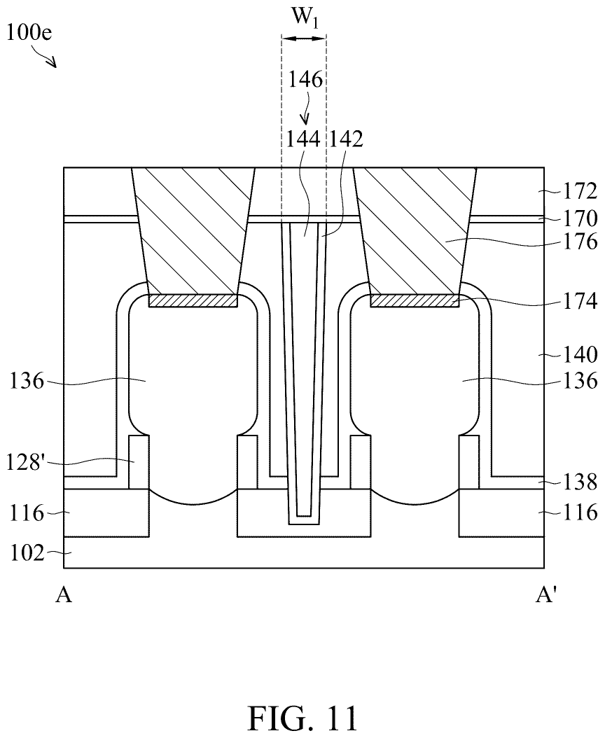

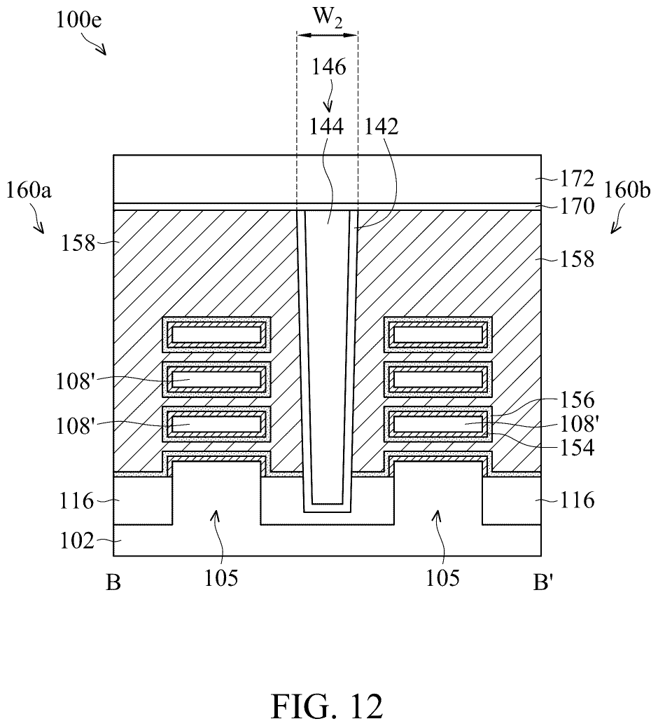

FIG. 11 illustrates a cross-sectional representation of the semiconductor structure 100e shown along line A-A′ in FIG. 7, in accordance with some embodiments. FIG. 12 illustrates a cross-sectional representation of the semiconductor structure 100e shown along line B-B′ in FIG. 7, in accordance with some embodiments.

As shown in FIGS. 10, 11 and 12, the first portion of the dielectric wall structure 146 between two adjacent S/D structures 136 has a first width W₁ along the second direction. The second portion of the dielectric wall structure 146 between the first gate structure 160a and the second gate structure 160b has a second width W₂ along the second direction. In some embodiments, the first width W₁ of the first portion of the dielectric wall structure 146 is smaller than the second width W₂ of the second portion of the dielectric wall structure 146. In some embodiments, the difference between the first width W₁ and the second width W₂ is in a range from about 2 nm to about 40 nm.

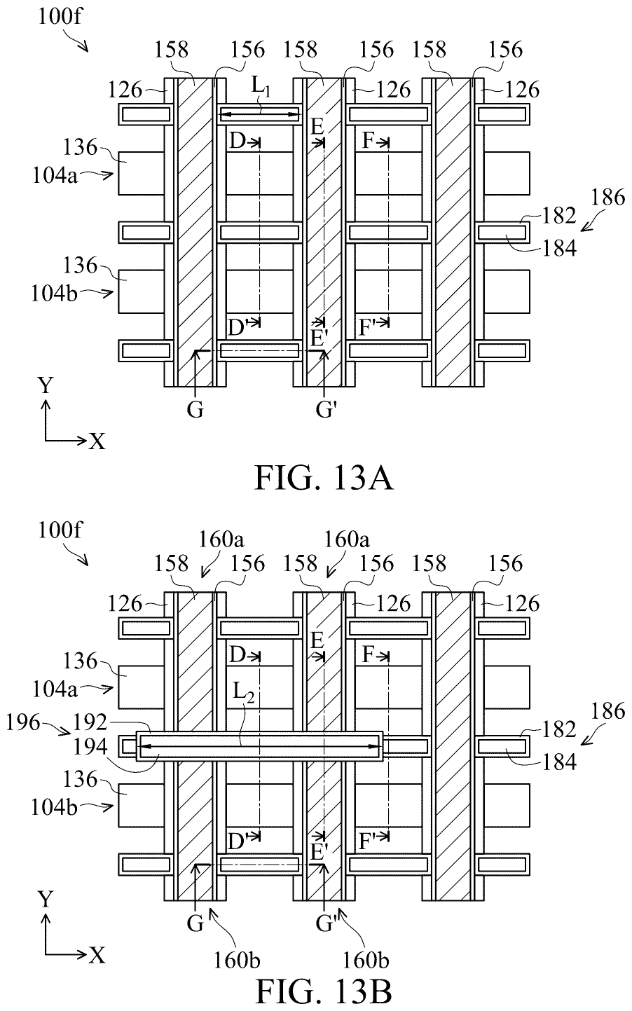

FIG. 13A shows a top-view representation of the semiconductor structure 100f after forming a first dielectric wall structure 186, in accordance with some embodiments. FIG. 13A includes elements that are similar to, or the same as, elements of the semiconductor structure 100a of FIG. 4. FIG. 13B shows a top-view representation of the semiconductor structure 100f after forming a second dielectric wall structure 196, in accordance with some embodiments. FIG. 13B includes elements that are similar to, or the same as, elements of the semiconductor structure 100a of FIG. 4.

The first dielectric wall structure 186 is formed firstly, and the second dielectric wall structure 196 is formed after the first dielectric wall structure 186. The first dielectric wall structure 186 is parallel to the second dielectric wall structure 196. The first dielectric wall structure 186 is also parallel to the nanostructures 108′. The first dielectric wall structure 186 has a first length L₁ along the first direction (e.g. x-axis), and the second dielectric wall structure 196 has a second length L₂ along the first direction (e.g. x-axis). In some embodiments, the first length L₁ is smaller than the second length L₂.

As shown in FIG. 13A, the first dielectric wall structure 186 is formed in the S/D region along the first direction (e.g. x-axis). The first dielectric wall structure 186 is formed between the S/D structure 136 and another S/D structure 136. It should be noted that the first dielectric wall structure 186 does not extend through the gate electrode layer 158. The first dielectric wall structure 186 may be through the gate spacer layer 126, but not through the gate dielectric layer 156. The first dielectric wall structure 186 is in direct contact with the gate spacer layer 126.

As shown in FIG. 13B, the second dielectric wall structure 196 is formed from the S/D region to the gate region along the first direction (e.g. x-axis). A portion of the second dielectric wall structure 196 overlaps a portion of the first dielectric wall structure 186. The second dielectric wall structure 196 divides or cuts the gate electrode layer 158 to form the first gate structure 160a and the second gate structure 160b. The second dielectric wall structure 196 also extends to a position between two adjacent S/D structures 136.

More specifically, the second dielectric wall structure 196 has a first portion, a second portion and a third portion. The first portion is between the S/D structure 136 and another S/D structure 136. The second portion is between two adjacent gate spacer layers 126. The third portion is between the first gate structure 160a and the second gate structure 160b.

FIGS. 14A-1 to 14E-1 illustrate cross-sectional representations of various stages of manufacturing the semiconductor structure 100f shown along line D-D′ in FIGS. 13A and 13B, in accordance with some embodiments. FIGS. 14A-2 to 14E-2 illustrate cross-sectional representations of various stages of manufacturing the semiconductor structure 100f shown along line E-E′ in FIGS. 13A and 13B, in accordance with some embodiments. FIGS. 14A-3 to 14E-3 illustrate cross-sectional representations of various stages of manufacturing the semiconductor structure 100f shown along line F-F′ in FIGS. 13A and 13B, in accordance with some embodiments. FIGS. 14A-4 to 14E-4 illustrate cross-sectional representations of various stages of manufacturing the semiconductor structure 100f shown along line G-G′ in FIGS. 13A and 13B, in accordance with some embodiments. FIGS. 14A-1 to 14E-4, 14A-2 to 14E-2, 14A-3 to 14E-3 and 14A-4 to 14E-4 include elements that are similar to, or the same as, elements of the semiconductor structure 100a of FIGS. 3A-1 to 3L-1, 3A-2 to 3L-2, 3A-3 to 3L-3 and 3A-4 to 3L-4.

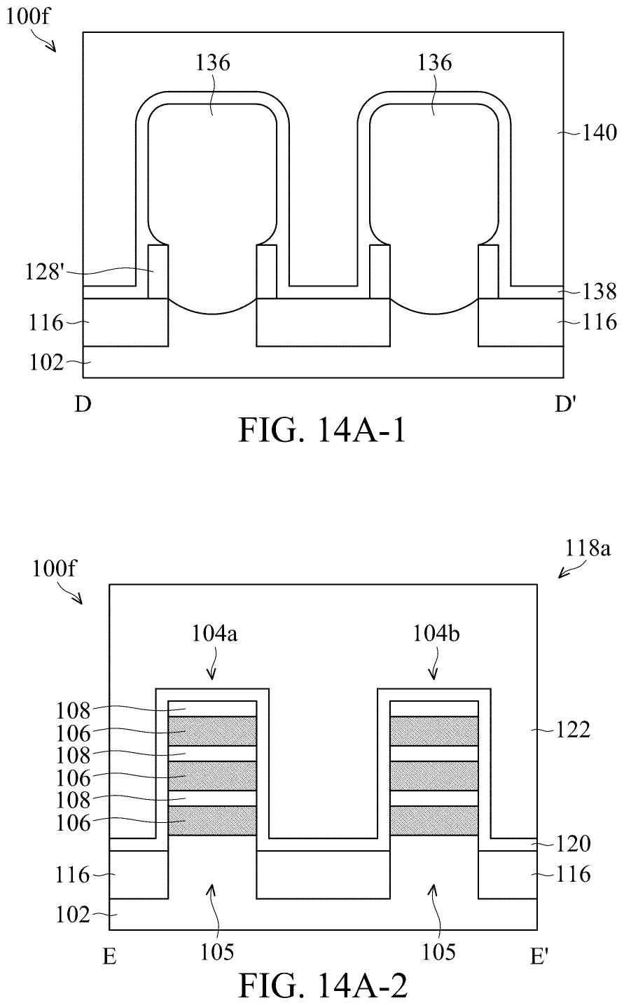

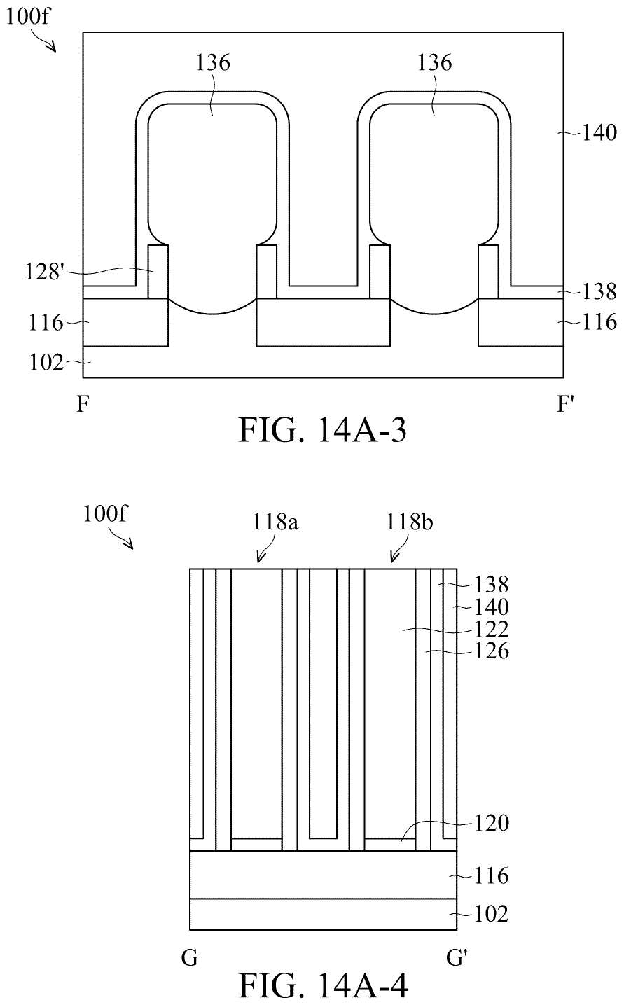

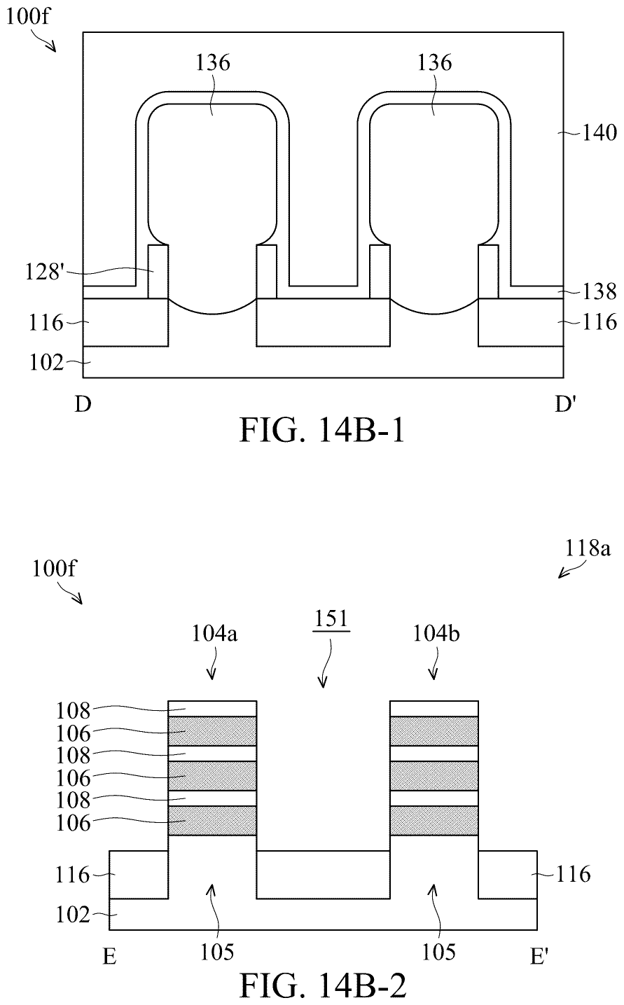

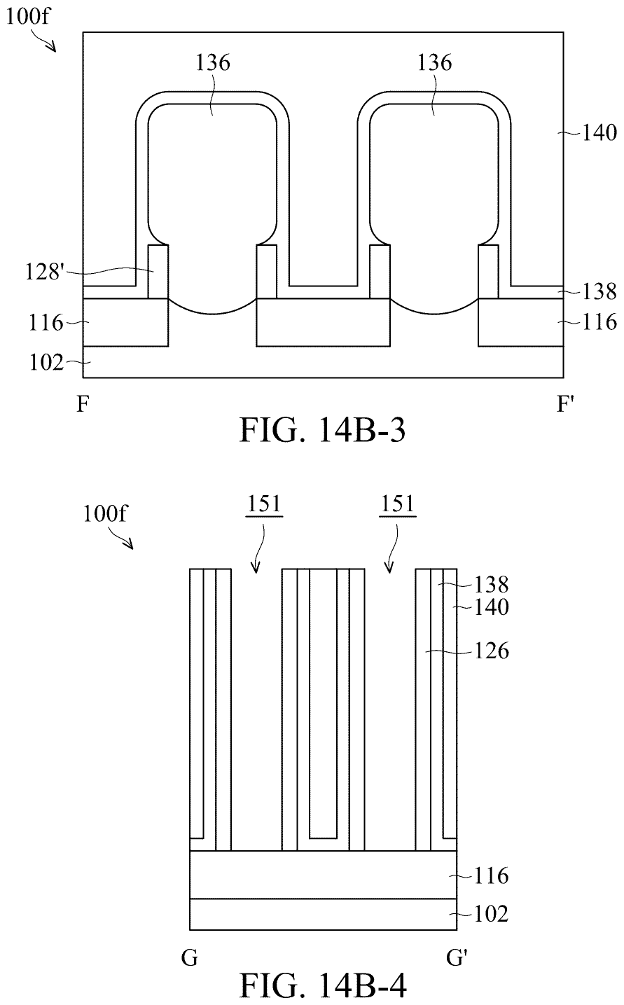

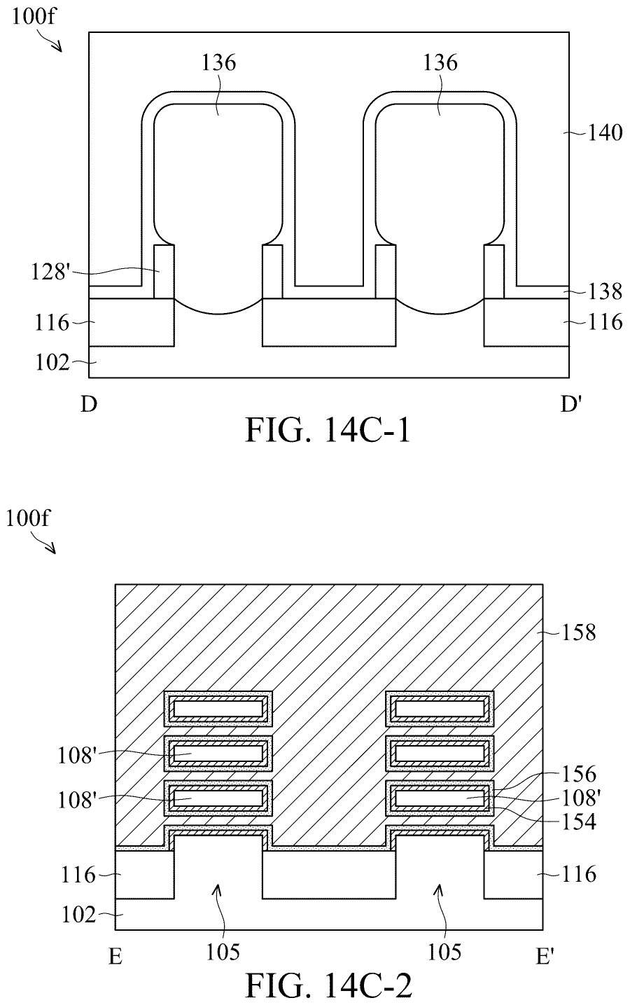

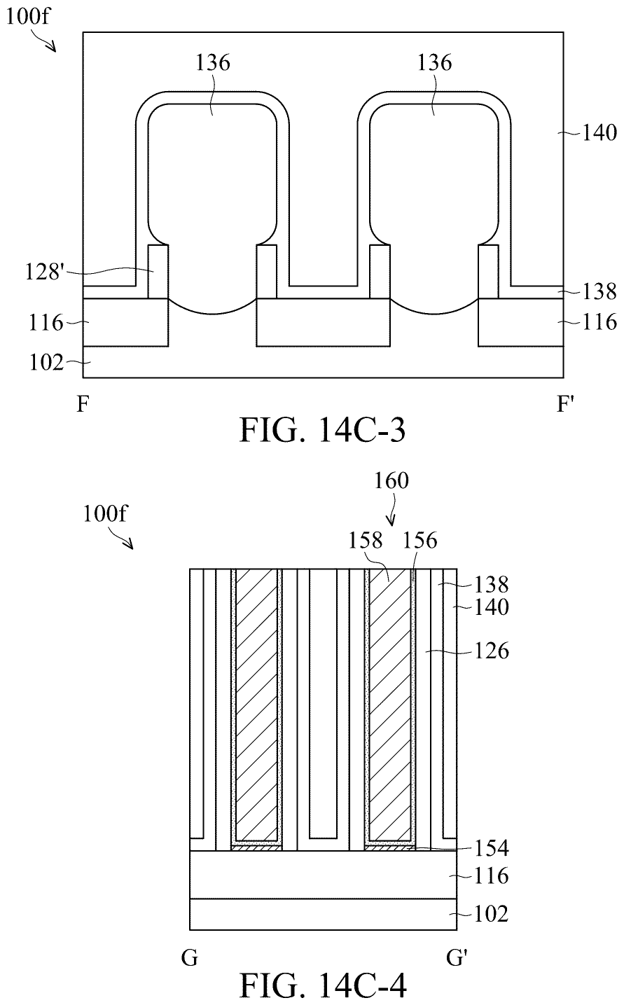

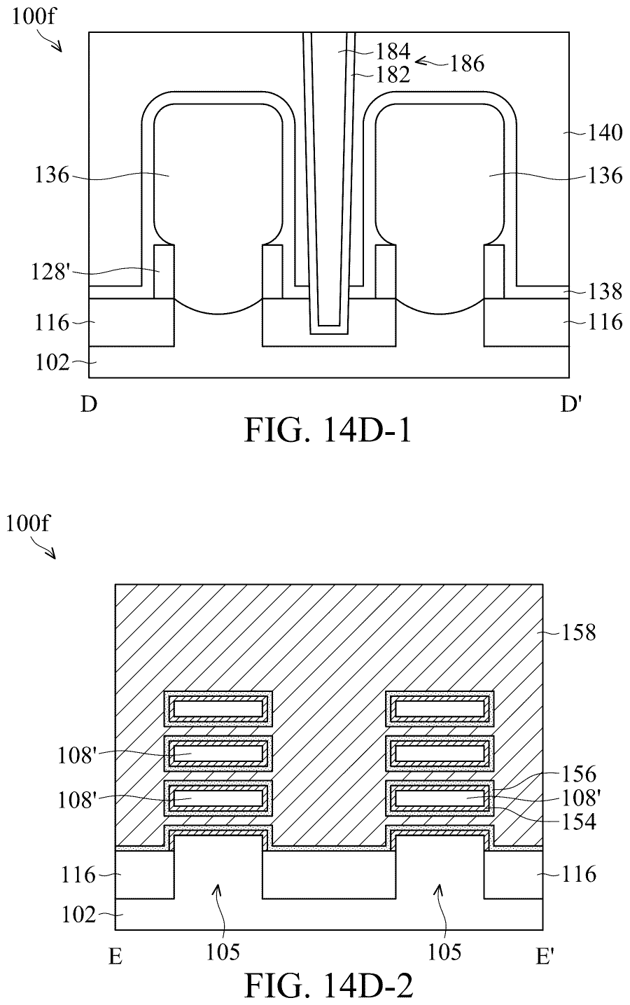

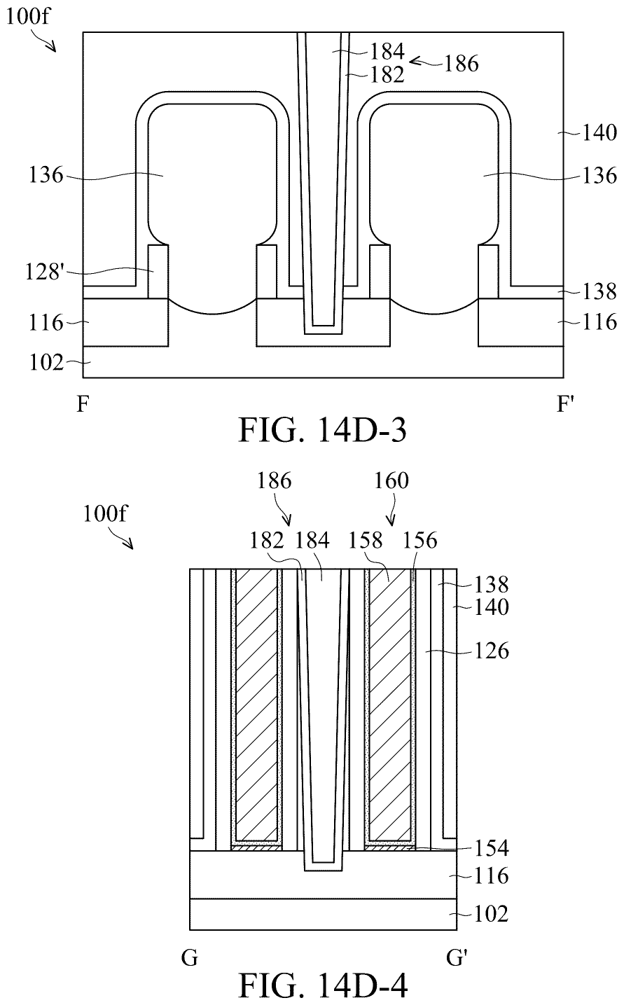

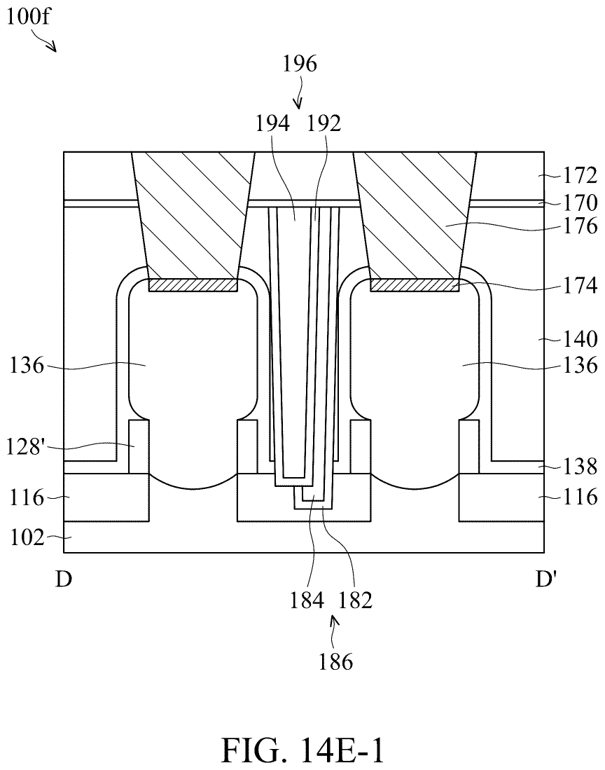

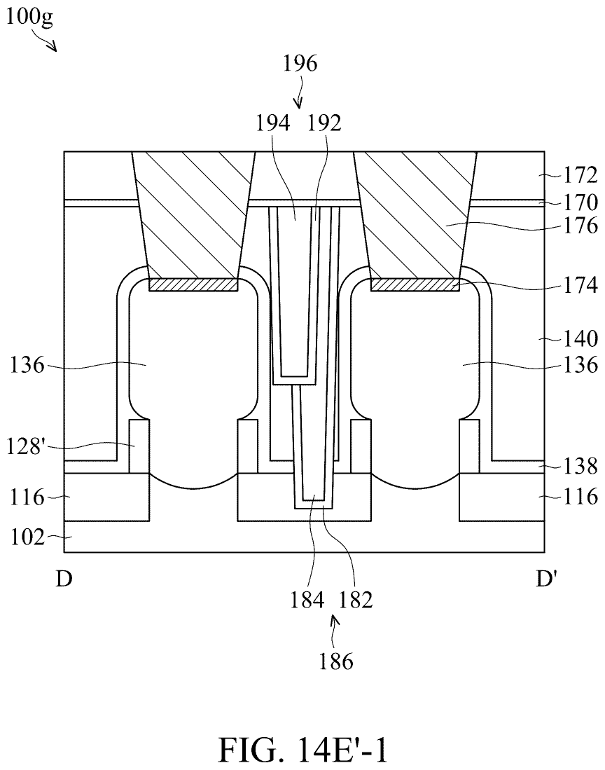

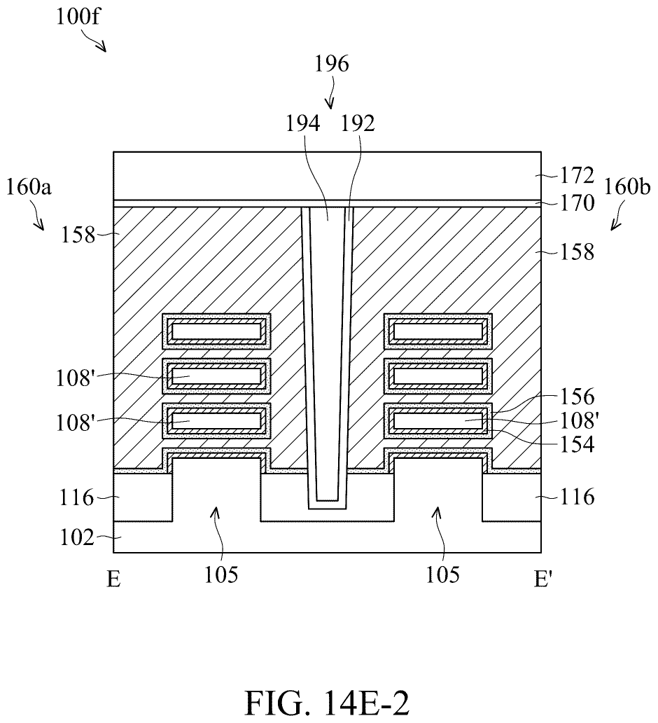

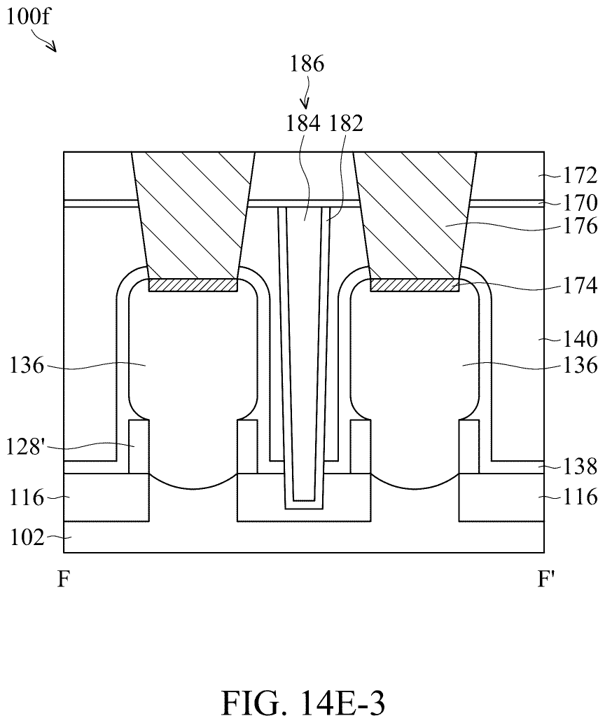

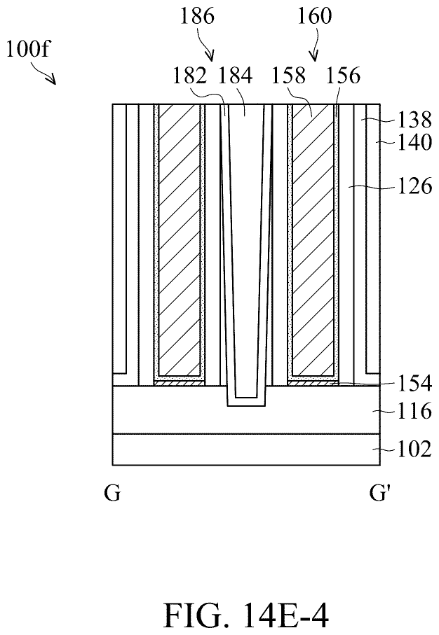

The semiconductor structure 100f as shown in FIGS. 14A-1, 14A-2 and 14A-3 is similar to the semiconductor structure 100a as shown in FIGS. 3F-1, 3F-2 and 3F-3. As shown in FIG. 14A-4, the first dummy gate structure 118a and the second dummy gate structure 118b are formed over the isolation structure 116. The gate spacer layer 126 is formed on the opposite sidewall surfaces of the first dummy gate structure 118a and the second dummy gate structure 118b.

Next, as shown in FIGS. 14B-1, 14B-2, 14B-3 and 14B-4, the dummy gate electrode layer 122 is removed to form the trench 151, and then the dummy gate dielectric layer 120 is removed, in accordance with some embodiments.

Afterwards, as shown in FIGS. 14C-1, 14C-2, 14C-3 and 14C-4, the first semiconductor material layers 106 are removed to form nanostructures 108′ (or channel layers 108′), and the interfacial layer 154, the gate dielectric layer 156, and the gate electrode layer 158 are formed in the trench 151, in accordance with some embodiments.

After the interfacial layers 154, the gate dielectric layers 156, and the gate electrode layers 158 are formed, a planarization process such as CMP or an etch-back process may be performed.

Next, as shown in FIGS. 14D-1, 14D-2, 14D-3 and 14D-4, the first dielectric wall structure 186 is formed between the two adjacent S/D structures 136, in accordance with some embodiments. It should be noted that the first dielectric wall structure 186 is formed in the S/D region, but not formed in the gate region.

The first dielectric wall structure 186 includes a liner layer 182 and a filling layer 184 formed on the liner layer 182. In some embodiments, the liner layer 182 is made of silicon nitride. In some embodiments, the liner layer 182 is formed by a chemical vapor deposition (CVD), a physical vapor deposition, (PVD), an atomic layer deposition (ALD), or other applicable processes. The filling layer 184 may be a single layer or multiple layers. In some embodiments, the filling layer 184 is made of silicon oxide (SiOx), silicon nitride (SiN), silicon carbide (SiC), silicon oxynitride (SiON), silicon carbon nitride (SiCN), silicon oxide carbonitride (SiOCN), and/or a combination thereof. In some embodiments, the filling layer 184 is formed by a chemical vapor deposition (CVD), a physical vapor deposition, (PVD), an atomic layer deposition (ALD), or other applicable processes.

The first dielectric wall structure 186 is formed by forming a trench (not shown) along the first direction (e.g. x-axis), and the trench is through the ILD layer 140. Next, the liner layer 142 and the filling layer 144 are formed in the trench. It should be noted that, as shown in FIG. 11D-2, the trench is not through the gate electrode layer 158.

It should be noted that the bottom surface of the first dielectric wall structure 186 is lower than the bottom surface of the S/D structure 136, as shown in FIG. 14D-1. In some embodiments, there is a distance between the bottom surface of the dielectric wall structure 146 and the bottom surface of the S/D structure 136, and the distance is in a range from about 10 nm to about 200 nm. In addition, as shown in FIG. 14D-4, the top surface of the isolation structure 116 is higher than the bottom surface of the first dielectric wall structure 186. In some embodiments, the first dielectric wall structure 186 is in direct contact with the gate spacer layer 126.

Afterwards, as shown in FIGS. 14E-1, 14E-2, 14E-3 and 14E-4, the second dielectric wall structure 196 is formed, in accordance with some embodiments. Next, the etch stop layer 170 is formed over the gate structure 142, and dielectric layer 172 is formed over the etch stop layer 170. The silicide layer 174 and the S/D contact structure 176 are formed over the S/D structure 136.

As shown in FIG. 14E-1, a portion of the first dielectric wall structure 186 is removed to form a second trench, and the second dielectric wall structure 196 is formed in the second trench. A portion of the second dielectric wall structure 196 is embedded in the first dielectric wall structure 186. The second dielectric wall structure 196 overlaps a portion of the first dielectric wall structure 186.

In some embodiments, the bottom surface of the first dielectric wall structure 186 is lower than the bottom surface of the second dielectric wall structure 196. In some embodiments, the width of the top surface of the first dielectric wall structure 186 is smaller than the width of the top surface of the second dielectric wall structure 196.

Furthermore, a portion of the S/D contact structure 176 is in direct contact with the first dielectric wall structure 186. The portion of the S/D contact structure 176 is embedded in the first dielectric wall structure 186.

The second dielectric wall structure 196 includes a liner layer 192 and a filling layer 194 formed on the liner layer 192. The liner layer 192 may be different from the liner layer 182. The filling layer 194 may be different from the filling layer 184. In some embodiments, the liner layer 192 is made of silicon nitride. In some embodiments, the liner layer 192 is formed by a chemical vapor deposition (CVD), a physical vapor deposition, (PVD), an atomic layer deposition (ALD), or other applicable processes. The filling layer 194 may be a single layer or multiple layers. In some embodiments, the filling layer 194 is made of silicon oxide (SiOx), silicon nitride (SiN), silicon carbide (SiC), silicon oxynitride (SiON), silicon carbon nitride (SiCN), silicon oxide carbonitride (SiOCN), and/or a combination thereof. In some embodiments, the filling layer 194 is formed by a chemical vapor deposition (CVD), a physical vapor deposition, (PVD), an atomic layer deposition (ALD), or other applicable processes.

As shown in FIG. 14E-2, the second dielectric wall structure 196 divides or cuts the gate electrode layer 158 to form the first gate structure 160a and the second gate structure 160b. The bottom surface of the second dielectric wall structure 196 is lower than the top surface of the isolation structure 116. The bottom surface of the second dielectric wall structure 196 is lower than the bottommost nanostructure 108′.

As shown in FIG. 14E-3, the first dielectric wall structure 186 is between two adjacent two S/D structures 136 to reduce the unwanted leakage current.

As shown in FIG. 14E-4, the bottom surface of the first dielectric wall structure 186 is lower than the top surface of the isolation structure 116.

It should be noted that the two adjacent S/D structures 136 are isolated or separated from the first dielectric wall structure 186 or the second dielectric wall structure 196, the unwanted connection between the two adjacent S/D structures 136 is prevented. Therefore, the leakage of the semiconductor structures 100f is reduced, and the performance of the semiconductor structures 100f is improved.

FIG. 14E′-1 illustrates a cross-sectional representation of a semiconductor structure 100g shown along line D-D′ in FIG. 13B, in accordance with some embodiments. The semiconductor structure 100g of FIG. 14E′-1 includes elements that are similar to, or the same as, elements of the semiconductor structure 100f of FIG. 14E-1.

FIG. 14E′-1 is are similar to, or the same as, FIG. 14E-1, the difference between FIG. 14E′-1 and FIG. 14E-1 is that the bottom surface of the second dielectric wall structure 196 is higher than the bottom surface of the first dielectric wall structure 186. In addition, the bottom surface of the second dielectric wall structure 196 is higher than the top surface of the isolation structure 116. The bottom surface of the second dielectric wall structure 196 is higher than the bottommost nanostructure 108′.

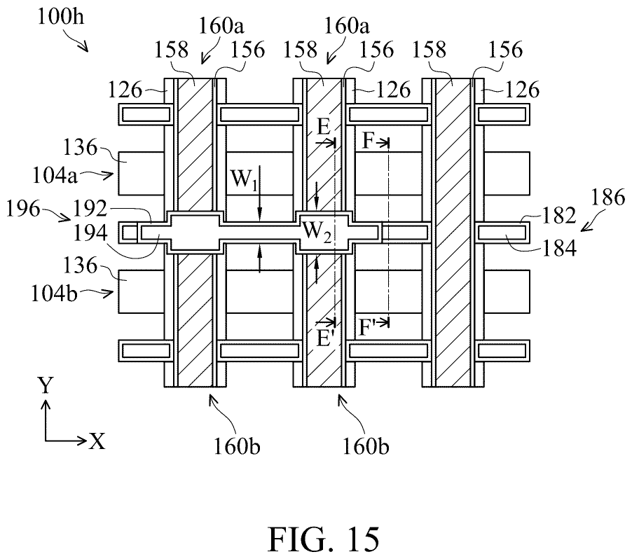

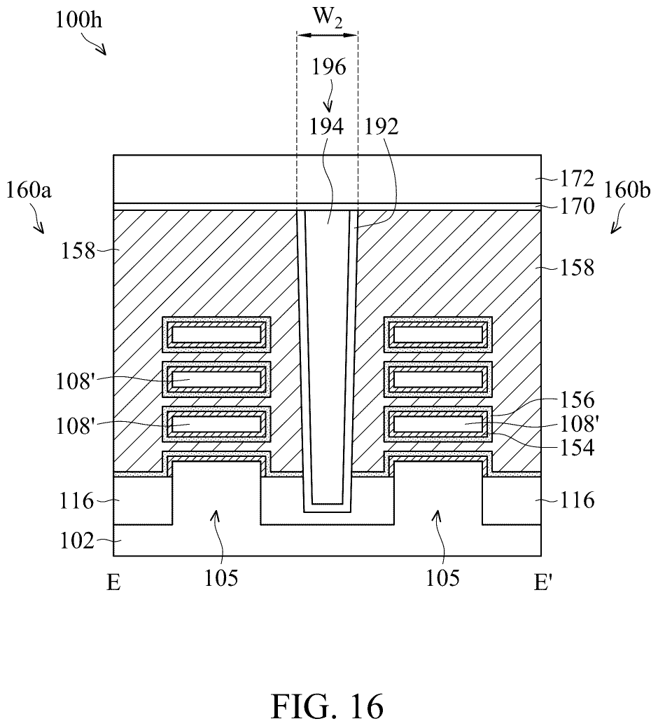

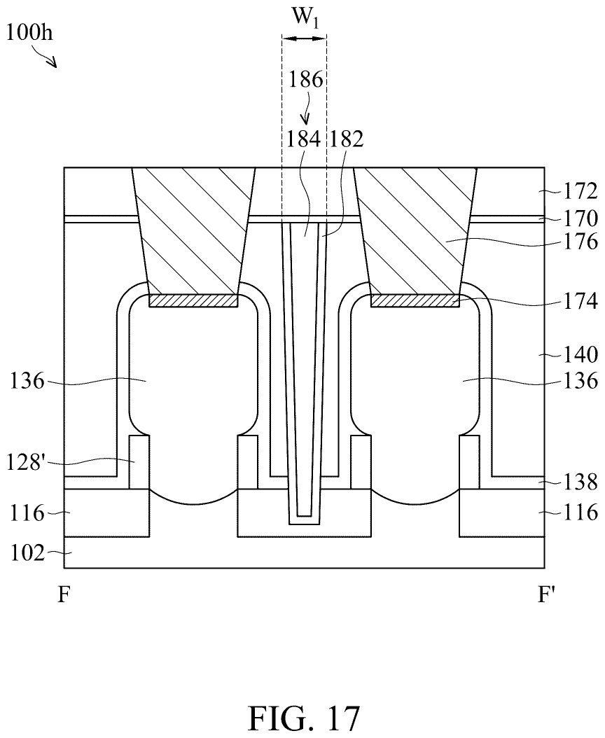

FIG. 15 shows a top-view representation of a semiconductor structure 100h, in accordance with some embodiments. FIG. 15 includes elements that are similar to, or the same as, elements of the semiconductor structure 100f of FIG. 13B. FIG. 16 illustrates a cross-sectional representation of the semiconductor structure 100h shown along line E-E′ in FIG. 15, in accordance with some embodiments. FIG. 17 illustrates a cross-sectional representation of the semiconductor structure 100h shown along line F-F′ in FIG. 15, in accordance with some embodiments.

As shown in FIG. 15, the second dielectric wall structure 196 has a cross-shaped structure when seen from a top-view. The second dielectric wall structure 196 does not have uniform width along the second direction (e.g. y-axis).

As shown in FIGS. 15, 16 and 17, the first dielectric wall structure 186 between two adjacent S/D structures 136 has a first width W₁ along the second direction. The second dielectric wall structure 196 between the first gate structure 160a and the second gate structure 160b has a second width W₂ along the second direction. In some embodiments, the first width W₁ of the first portion of the dielectric wall structure 146 is smaller than the second width W₂ of the second portion of the dielectric wall structure 146. In some embodiments, the difference between the first width W₁ and the second width W₂ is in a range from about 2 nm to about 40 nm.

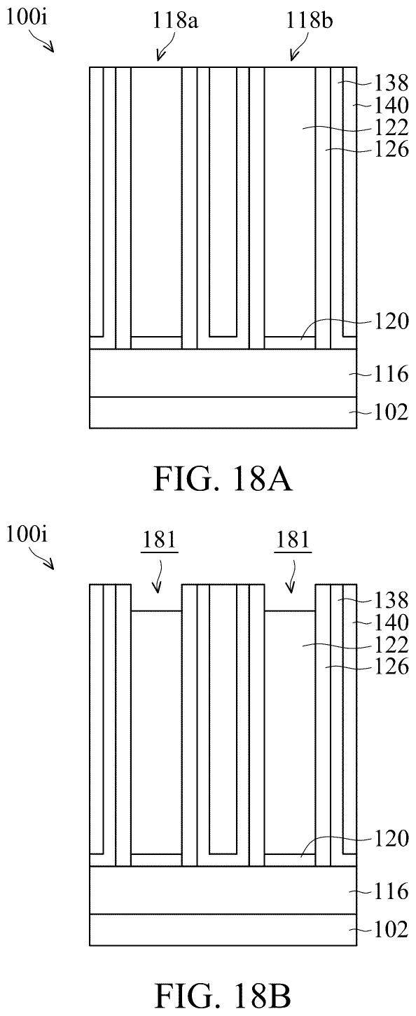

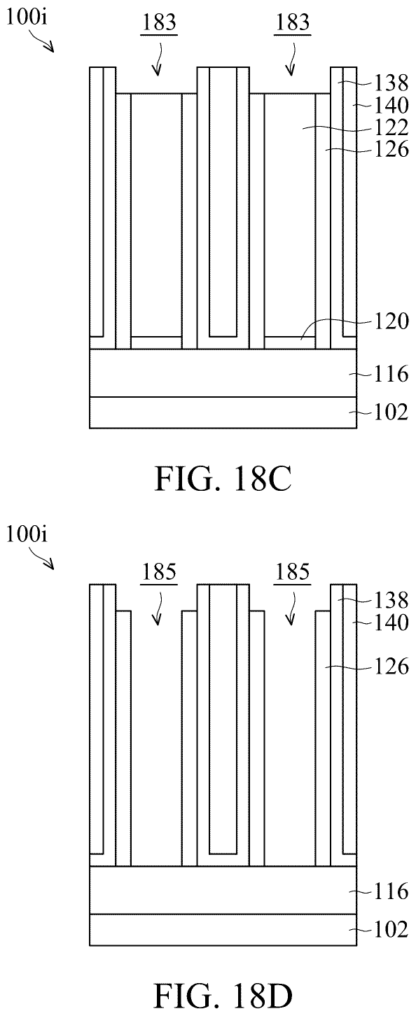

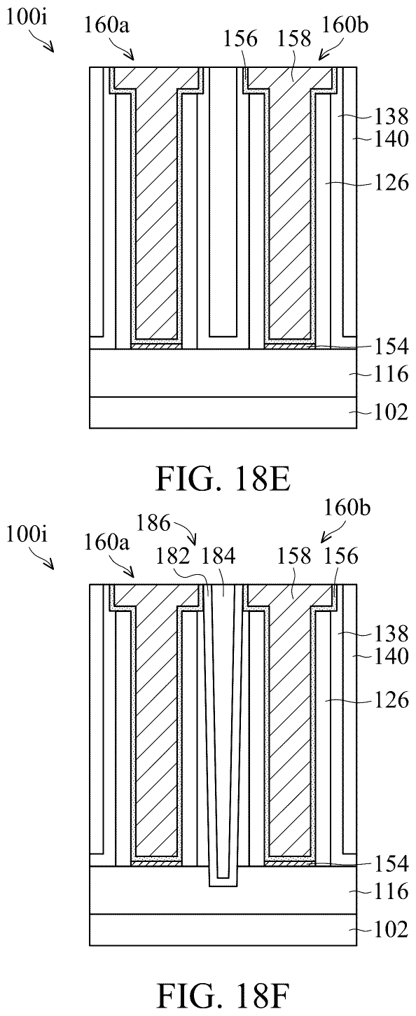

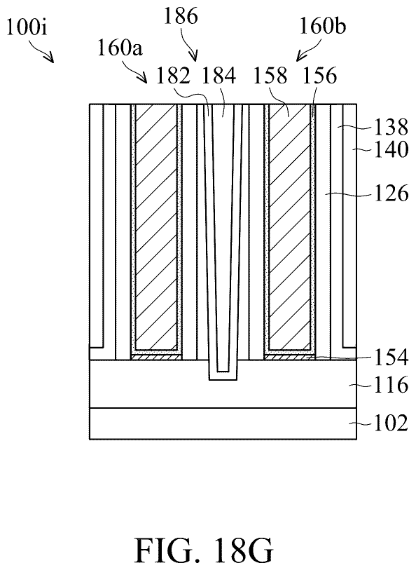

FIGS. 18A to 18G illustrate cross-sectional representations of various stages of manufacturing a semiconductor structure 100i shown along line F-F′ in FIGS. 13A and 13B, in accordance with some embodiments.

As shown in FIG. 18A, the first dummy gate structure 118a and the second dummy gate structure 118b are formed on the isolation structure 116. The gate spacer layers 126 are formed on opposite sidewall surfaces of the first dummy gate structure 118a and the second dummy gate structure 118b.

Next, as shown in FIG. 18B, the top portion of the dummy gate electrode layer 122 is removed to form an opening 181, in accordance with some embodiments. As a result, a portion of the gate spacer layer 126 is exposed.

Afterwards, as shown in FIG. 18C, the exposed gate spacer layer 126 is removed to form a recess 183, in accordance with some embodiments. As a result, a portion of the CESL 138 is exposed.

Next, as shown in FIG. 18D, the remaining dummy gate electrode layer 122 and the dummy gate dielectric layer 120 are removed to form a trench 185, in accordance with some embodiments. Note that the trench 185 has a T-shaped structure. In some embodiments, when the remaining dummy gate electrode layer 122 and the dummy gate dielectric layer 120 are removed, a portion of the CESL 138 is also removed.

Afterwards, as shown in FIG. 18E, after the first semiconductor layers are removed to form the nanostructures 108′, the gate dielectric layer 156 and the gate electrode layer 158 are formed in the T-shaped trench 185 to form the first gate structure 160a and the second gate structure 160b, in accordance with some embodiments. Note that a portion of the gate spacer layer 126 may be removed while the trench 185 is formed, and therefore the gate structure 160 is in direct contact with the CESL 138. The gate structures 160 also have T-shaped structure since the trench 185 has T-shaped structure.

Next, as shown in FIG. 18F, the first dielectric wall structure 186 is formed between the two adjacent gate structures 160, in accordance with some embodiments. The sidewall surface of the dielectric wall structure 186 is in direct contact with the sidewall surfaces of the first gate structure 160a and the second gate structure 160b.

Afterwards, as shown in FIG. 18G, a planarization process is performed on the dielectric wall structure 186, the first gate structure 160a and the second gate structure 160b, in accordance with some embodiments. The top portion of the T-shaped first gate structure 160a and the second gate structure 160b are removed. In some embodiments, the planarization process includes CMP process or an etch-back process.

It should be noted that if the first gate structure 160a and the second gate structure 160b have rectangular shape, when the first dielectric wall structure 186 is misaligned, the first dielectric wall structure 186 may be too close to the first gate structure 160a or the second gate structure 160b. The performance of the first gate structure 160a or the second gate structure 160b may be degraded. In this embodiments, since the first gate structure 160a and the second gate structure 160b have T-shaped structure, even if the top portion of the T-shaped first gate structure 160a or the second gate structure 160b is in direct contact with the first dielectric wall structure 186, the top portion of the T-shaped first gate structure 160a or the second gate structure 160b will be removed. The T-shaped first gate structure 160a or the second gate structure 160b can control the distance between the first gate structure 160a or the second gate structure 160b and the first dielectric wall structure 186. Therefore, the phenomenon of the bottom portion of the first gate structure 160a or the second gate structure 160b in direct contact with the first dielectric wall structure 186 does not occur.

Since the two adjacent S/D structures 136 are isolated or separated from the dielectric wall structure 146, the first dielectric wall structure 186 or the second dielectric wall structure 196, the unwanted connection between the two adjacent S/D structures 136 is prevented. Therefore, the leakage of the semiconductor structures 100a-100i is reduced, and the performance of the semiconductor structures 100a-100i are improved.

It should be noted that same elements in FIGS. 1A to 18G may be designated by the same numerals and may include similar or the same materials and may be formed by similar or the same processes; therefore such redundant details are omitted in the interest of brevity. In addition, although FIGS. 1A to 18G are described in relation to the method, it will be appreciated that the structures disclosed in FIGS. 1A to 18G are not limited to the method but may stand alone as structures independent of the method. Similarly, although the methods shown in FIGS. 1A to 18G are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes a first fin structure and a second fin structure formed over a substrate. The first fin structure includes first nanostructures, and the second fin structure includes second nanostructures along a first direction (e.g. x-axis). A first gate structure formed over the first nanostructures along the second direction (e.g. y-direction) and a second gate structure formed along the second direction (e.g. y-direction).

In some embodiments, the dielectric wall structure has a first portion and a second portion, the first portion is between two adjacent S/D structures, and the second portion is between the first gate structure and the second gate structure. In some embodiments, the first dielectric wall structure and the second dielectric wall structure are formed by two different steps. The first dielectric wall structure and the second dielectric wall structure are parallel to each other along the first direction (e.g. x-axis). The first dielectric wall structure is between two adjacent S/D structures, and the second dielectric wall structure is between the first gate structure and the second gate structure. Since the two adjacent S/D structures are isolated or separated from the dielectric wall structure, the first dielectric wall structure or the second dielectric wall structure, the unwanted connection between the two adjacent S/D structures can be prevented. Therefore, the leakage of the semiconductor structures is reduced, and the performances of the semiconductor structures are improved.

In some embodiments, a semiconductor structure is provided. The semiconductor structure includes first nanostructures formed over a substrate along a first direction, and second nanostructures formed over the substrate along the first direction. The semiconductor structure includes a first gate structure formed over the first nanostructures along a second direction, and a first S/D structure formed adjacent to the first gate structure. The semiconductor structure also includes a second gate structure formed over the second nanostructures along the second direction, and a second S/D structure formed adjacent to the second gate structure. The semiconductor structure further includes a dielectric wall structure formed along the first direction. The dielectric wall structure includes a first portion between the first S/D structure and the second S/D structure and a second portion between the first gate structure and the second gate structure.

In some embodiments, a semiconductor structure is provided. The semiconductor structure includes first nanostructures formed over a substrate along a first direction, and second nanostructures parallel to the first nanostructures. The semiconductor structure includes a first gate structure formed over the first nanostructures along a second direction, and a first S/D structure formed adjacent to the first gate structure. The semiconductor structure also includes a second gate structure formed over the second nanostructures along the second direction, and a second S/D structure formed adjacent to the second gate structure. The semiconductor structure includes a first dielectric wall structure parallel to the first nanostructures, and the first dielectric wall structure is between the first S/D structure and the second S/D structure. The semiconductor structure also includes a second dielectric wall structure between the first gate structure and the second gate structure, and the second dielectric wall structure further extends to a position between the first S/D structure and the second S/D structure.

In some embodiments, a method for forming a semiconductor structure is provided. The method includes forming a first fin structure and a second fin structure over a substrate, respectively, and the first fin structure includes first semiconductor material layers and second semiconductor material layers alternately stacked, and the second fin structure includes first semiconductor material layers and second semiconductor material layers alternately stacked. The method includes forming a first dummy gate structure over the first fin structure and the second fin structure, and removing a portion of the first fin structure to form a first S/D structure on the first side the first dummy gate structure. The method includes removing a portion of the second fin structure to form a second S/D structure on the first side the first dummy gate structure, and replacing the first dummy gate structure with a first gate structure. The method also includes forming a first dielectric wall structure between the first S/D structure and the second S/D structure, and forming a second dielectric wall structure to divide the first gate structure into two portions. The second dielectric wall structure overlaps a portion of the first dielectric wall structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
first nanostructures formed over a substrate along a first direction;
second nanostructures formed over the substrate along the first direction;
a first gate structure formed over the first nanostructures along a second direction;
a first S/D structure formed adjacent to the first gate structure;
a second gate structure formed over the second nanostructures along the second direction;
a second S/D structure formed adjacent to the second gate structure; and
a dielectric wall structure formed along the first direction, wherein the dielectric wall structure comprises a first portion between the first S/D structure and the second S/D structure and a second portion between the first gate structure and the second gate structure.

2. The semiconductor structure as claimed in claim 1, wherein the first gate structure comprises a gate dielectric layer and a gate electrode layer, and the gate dielectric layer is formed on a sidewall surface of the dielectric wall structure when seen from a top-view.

3. The semiconductor structure as claimed in claim 1, further comprising:
a first gate spacer layer formed on a sidewall surface of the first gate structure; and
a second gate spacer layer formed on a sidewall surface of the second gate structure, wherein the dielectric wall structure comprises a third portion between the first gate spacer layer and the second gate spacer layer.

4. The semiconductor structure as claimed in claim 1, further comprising:
an isolation structure formed over the substrate, wherein a top surface of the isolation structure is higher than a bottom surface of the dielectric wall structure.

5. The semiconductor structure as claimed in claim 1, wherein a bottom surface of the dielectric wall is lower than a bottom surface of the first S/D structure.

6. The semiconductor structure as claimed in claim 1, wherein the first portion of the dielectric wall structure has a first width along the second direction, the second portion of the dielectric wall structure has a second width along the second direction, and the first width is smaller than the second width.

7. The semiconductor structure as claimed in claim 6, wherein the dielectric wall structure has a cross-like shape structure when seen from a top-view.

8. The semiconductor structure as claimed in claim 1, further comprising:
a first S/D contact structure formed over the first S/D structure, wherein a portion of the first S/D contact structure is embedded in the dielectric wall structure.

9. A semiconductor structure, comprising:
first nanostructures formed over a substrate along a first direction;
second nanostructures parallel to the first nanostructures;
a first gate structure formed over the first nanostructures along a second direction;
a first S/D structure formed adjacent to the first gate structure;
a second gate structure formed over the second nanostructures along the second direction;
a second S/D structure formed adjacent to the second gate structure;
a first dielectric wall structure parallel to the first nanostructures, wherein the first dielectric wall structure is between the first S/D structure and the second S/D structure; and
a second dielectric wall structure between the first gate structure and the second gate structure, wherein the second dielectric wall structure further extends to a position between the first S/D structure and the second S/D structure.

10. The semiconductor structure as claimed in claim 9, further comprising:
a first gate spacer layer formed on a sidewall surface of the first gate structure, wherein the first gate spacer layer is in direct contact with the first dielectric wall structure.

11. The semiconductor structure as claimed in claim 9, wherein the first dielectric wall structure has a first length along the second direction, the second dielectric wall structure has a second length along the second direction, and the first length is smaller than the second length.

12. The semiconductor structure as claimed in claim 9, wherein the first dielectric wall structure does not extend through the first gate structure.

13. The semiconductor structure as claimed in claim 9, wherein a bottom surface of the first dielectric wall structure is lower than a bottom surface of the second dielectric wall structure.

14. The semiconductor structure as claimed in claim 9, further comprising:
a first S/D contact structure formed over the first S/D structure, wherein a portion of the first S/D contact structure is embedded in the first dielectric wall structure.

15. The semiconductor structure as claimed in claim 9, wherein the first dielectric wall structure has a first portion between the first S/D structure and the second S/D structure and a second portion between the first gate structure and the second gate structure, the first portion has a first width along the second direction, the second portion has a second width along the second direction, and the first width is smaller than the second width.

16. The semiconductor structure as claimed in claim 9, wherein a portion of the second dielectric wall structure is embedded in the first dielectric wall structure.

17. A method for forming a semiconductor structure, comprising:
forming a first fin structure and a second fin structure over a substrate, wherein the first fin structure comprises first semiconductor material layers and second semiconductor material layers alternately stacked, and the second fin structure comprises first semiconductor material layers and second semiconductor material layers alternately stacked;
forming a first dummy gate structure over the first fin structure and the second fin structure;
removing a portion of the first fin structure to form a first S/D structure on a first side the first dummy gate structure;
removing a portion of the second fin structure to form a second S/D structure on the first side the first dummy gate structure;
replacing the first dummy gate structure with a first gate structure; forming a first dielectric wall structure between the first S/D structure and the second S/D structure; and
forming a second dielectric wall structure to divide the first gate structure into two portions, wherein the second dielectric wall structure overlaps a portion of the first dielectric wall structure.

18. The method for forming the semiconductor structure as claimed in claim 17, further comprising:
forming a gate spacer layer on a sidewall surface of the first dummy gate structure;
removing a top portion of the first dummy gate structure;
removing a top portion of the gate spacer layer;
removing a bottom portion of the first dummy gate structure to form a T-shaped trench; and
forming the first gate structure in the T-shaped trench.

19. The method for forming the semiconductor structure as claimed in claim 17, further comprising:
forming an isolation structure over the substrate, wherein the first fin structure and the second fin structure extend above the isolation structure; and
removing a portion of the isolation structure when forming the first dielectric wall structure, wherein a bottom surface of the first dielectric wall structure is lower than a top surface of the isolation structure.

20. The method for forming the semiconductor structure as claimed in claim 17, further comprising:
removing a portion of the first dielectric wall structure when forming the second dielectric wall structure.
